(19) United States
(12) Patent Application Publication
(10) Pub. No.: US 2024/0422987 A1
(43) Pub. Date: Dec. 19, 2024

(54) SEMICONDUCTOR MEMORY DEVICES

(71) Applicant: Samsung Electronics Co., Ltd., Suwon-si (KR)

(72) Inventors: Kyung Hwan Lee, Suwon-si (KR); Myung Hun Woo, Suwon-si (KR); Dae Won Ha, Suwon-si (KR)

(21) Appl. No.: 18/398,336

(22) Filed: Dec. 28, 2023

(30) Foreign Application Priority Data
Jun. 15, 2023 (KR) 10-2023-0077021

(51) Int. Cl. H10B 51/30; H10B 51/40

(52) U.S. Cl. CPC H10B 51/30; H10B 51/40

(57) ABSTRACT

There is provided a semiconductor memory device comprising: a first word line; a second word line spaced apart from the first word line, a back gate electrode between the first word line and the second word line; a first channel pattern between the first word line and the back gate electrode; a second channel pattern between the second word line and the back gate electrode; a first gate insulating film between the first word line and the first channel pattern; a second gate insulating film between the second word line and the second channel pattern; a first bit line on the first channel pattern and the second channel pattern, wherein the first bit line is connected to the first channel pattern; and a second bit line on the first channel pattern and the second channel pattern, wherein the second bit line is connected to the second channel pattern.

### CROSS-REFERENCE TO RELATED APPLICATION

This application claims priority from Korean Patent Application No. 10-2023-0077021 filed on Jun. 15, 2023 in the Korean Intellectual Property Office, and all the benefits accruing therefrom under 35 U.S.C. 119, the contents of which in its entirety are herein incorporated by reference.

### BACKGROUND

The present disclosure relates to semiconductor memory devices, and more particularly, to semiconductor memory devices including a vertical channel transistor (VCT).

In order to satisfy the excellent performance and low price of semiconductor memory devices demanded by consumers, it is desired to increase the degree of integration of the semiconductor memory devices. Since the degree of integration of the semiconductor memory devices is an important factor in determining the price of the product, the increased degree of integration is particularly required.

Since the degree of integration of two-dimensional or planar semiconductor memory devices is mainly determined by an area occupied by unit memory cells, it is greatly affected by a level of technology for forming a fine pattern. However, since ultra-expensive equipment may be needed to form the fine pattern, the degree of integration of the two-dimensional semiconductor memory devices is increasing, but is still limited. Accordingly, semiconductor memory devices including a vertical channel transistor having a channel extending in a vertical direction are proposed.

### SUMMARY

Aspects of the present disclosure provide semiconductor memory devices capable of having the improved degree of integration and electrical characteristics.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor memory device comprising a first word line extending in a first direction; a second word line spaced apart from the first word line in a second direction that intersects the first direction, wherein the second word line extends in the first direction; a back gate electrode between the first word line and the second word line, wherein the back gate electrode extends in the first direction; a first channel pattern between the first word line and the back gate electrode; a second channel pattern between the second word line and the back gate electrode; a first gate insulating film between the first word line and the first channel pattern, wherein the first gate insulating film includes a first ferroelectric material film; a second gate insulating film between the second word line and the second channel pattern, wherein the second gate insulating film includes a second ferroelectric material film; a first bit line on the first channel pattern and the second channel pattern, wherein the first bit line extends in the second direction and is connected to the first channel pattern; and a second bit line on the first channel pattern and the second channel pattern, wherein the second bit line is spaced apart from the first bit line in the first direction, and wherein the second bit line extends in the second direction and is connected to the second channel pattern.

According to another aspect of the present disclosure, there is provided a semiconductor memory device comprising a first source line that extends in a first direction; a second source line that extends in the first direction, wherein the second source line is spaced apart from the first source line in a second direction that intersects the first direction; a first word line on the first source line and the second source line, wherein the first word line extends in the second direction; a second word line on the first source line and the second source line, wherein the second word line is spaced apart from the first word line in the first direction and extends in the second direction; a first channel pattern between the first word line and the second word line, wherein the first channel pattern is connected to the first source line; a second channel pattern between the first word line and the second word line, wherein the second channel pattern is connected to the second source line; a first gate insulating film between the first word line and the first channel pattern, wherein the first gate insulating film includes a first ferroelectric material film; a second gate insulating film between the second word line and the second channel pattern, wherein the second gate insulating film includes a second ferroelectric material film; a first bit line on the first channel pattern and the second channel pattern, wherein the first bit line is connected to the first channel pattern and extends in the first direction; and a second bit line on the first channel pattern and the second channel pattern, wherein the second bit line is connected to the second channel pattern and spaced apart from the first bit line in the second direction, and wherein the second bit line extends in the first direction.

According to still another aspect of the present disclosure, there is provided a semiconductor memory device comprising a peripheral gate structure on a substrate; back gate electrodes on the peripheral gate structure, wherein the back gate electrodes extend in a first direction; a first word line between a first back gate electrode and a second back gate electrode among the back gate electrodes, wherein the first back gate electrode and the second back gate electrode are adjacent to each other in a second direction that intersects the first direction, and wherein the first word line extends in the first direction; a second word line between the first back gate electrode and the second back gate electrode, wherein the second word line extends in the first direction; a first channel pattern between the first back gate electrode and the first word line; a second channel pattern between the second back gate electrode and the second word line; a gate separation pattern between the first word line and the second word line, wherein the gate separation pattern includes a horizontal portion and a protrusion, wherein the protrusion of the gate separation pattern protrudes from the horizontal portion of the gate separation pattern in a third direction that intersects the first direction and the second direction, wherein a width of the horizontal portion of the gate separation pattern in the second direction is greater than a width of the protrusion of the gate separation pattern in the second direction, and wherein the protrusion of the gate separation pattern is closer than the horizontal portion of the gate separation pattern to the peripheral gate structure in the third direction; a first gate insulating film between the first word line and the first channel pattern, wherein the first gate insulating film includes a first ferroelectric material film; a second gate insulating film between the second word line and the second channel pattern, wherein the second gate insulating film includes a second ferroelectric material film; a first bit line on the first channel pattern and the second channel pattern, wherein the first bit line is connected to the first channel pattern and extends in the second direction; and a second bit line on the first channel pattern and the second channel pattern, wherein the second bit line is connected to the second channel pattern, spaced apart from the first bit line in the first direction, and extends in the second direction.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan layout view for describing a semiconductor memory device according to some example embodiments;

FIG. 2 illustrates the semiconductor memory device of FIG. 1 without bit lines;

FIGS. 3, 4, and 5 are cross-sectional views taken along lines A-A′, B-B′, and C-C′ of FIG. 1, respectively;

FIG. 6 is an enlarged view of part P of FIG. 3;

FIG. 7 is a plan view for describing a channel pattern of FIG. 1;

FIGS. 8 to 11 are cross-sectional views for each describing a semiconductor device according to some example embodiments;

FIG. 12 is a plan view for describing a semiconductor memory device according to some example embodiments;

FIG. 13 is a cross-sectional view for describing a semiconductor memory device according to some example embodiments;

FIG. 14 is a cross-sectional view for describing a semiconductor memory device according to some example embodiments;

FIG. 15 is a cross-sectional view for describing a semiconductor memory device according to some example embodiments;

FIGS. 16 to 32 are views for describing a method for manufacturing a semiconductor memory device according to some example embodiments.

### DETAILED DESCRIPTION OF THE EMBODIMENTS

Terms “first”, “second” and the like are used herein to describe various elements or components, but these elements or components are not limited by these terms. These terms are used only to distinguish one element or component from another element or component. Therefore, a first element or component mentioned below could be termed a second element or component without departing from the scope of the present disclosure.

As used herein, the singular forms “a” and “an” are intended to include the plural forms as well, unless the context clearly indicates otherwise.

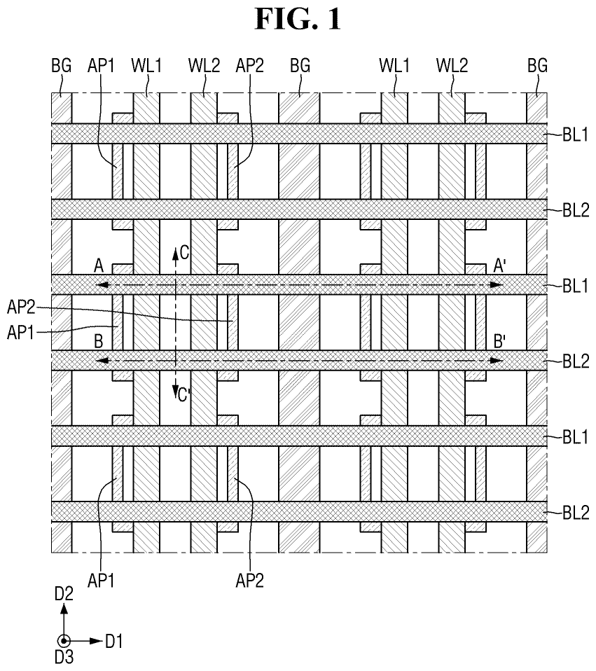

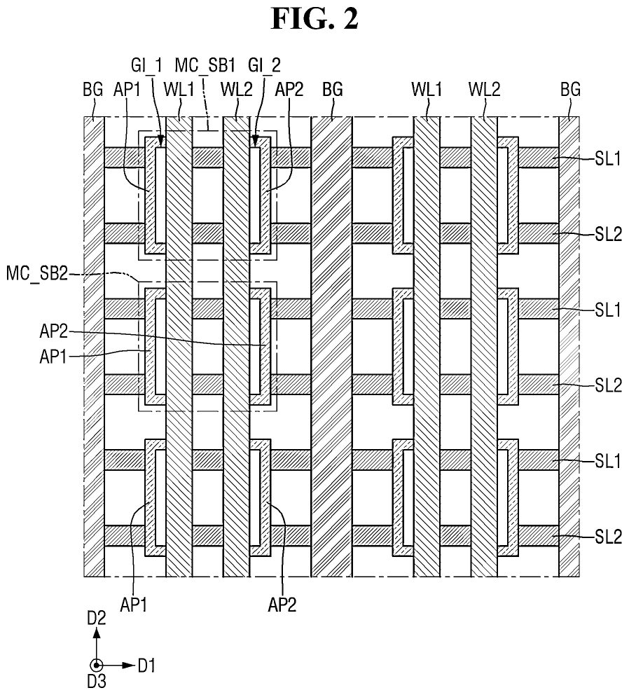

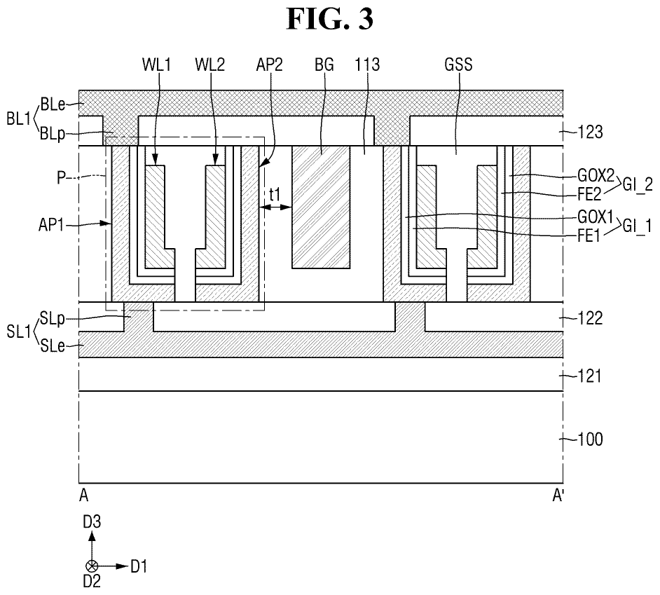

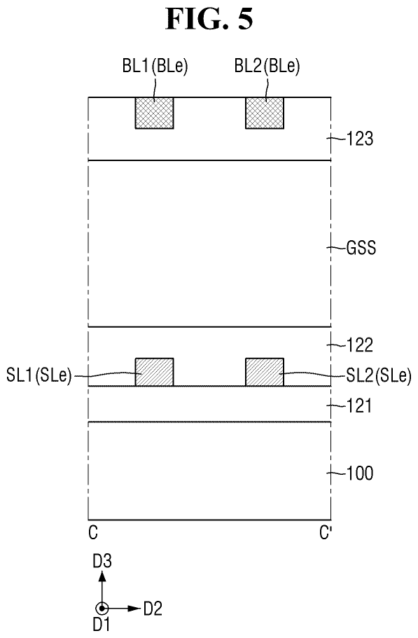

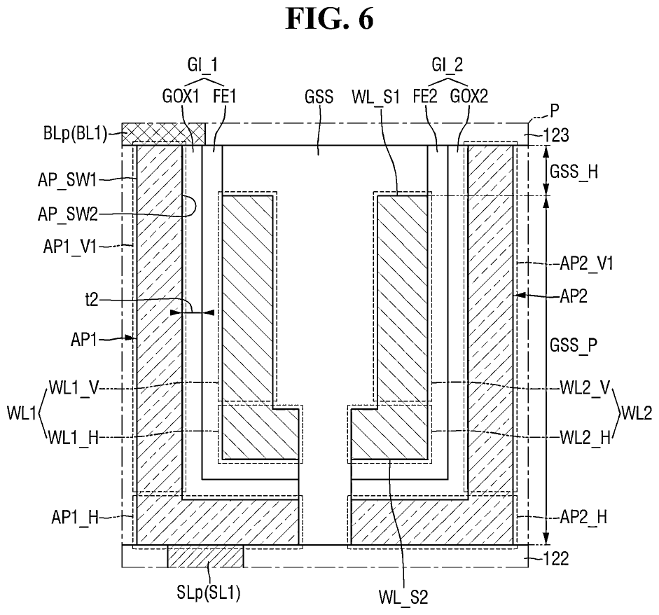

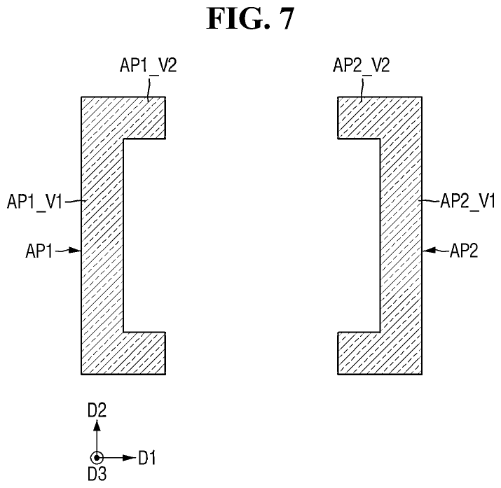

FIG. 1 is a plan layout view for describing a semiconductor memory device according to some example embodiments. FIG. 2 illustrates the semiconductor memory device of FIG. 1 without bit lines. FIGS. 3, 4, and 5 are cross-sectional views taken along lines A-A′, B-B′, and C-C′ of FIG. 1, respectively. FIG. 6 is an enlarged view of part P of FIG. 3. FIG. 7 is a plan view for describing a channel pattern of FIG. 1.

For reference, it is illustrated in FIG. 2 that each of gate insulating films GI_1 and GI_2 (each of a first gate insulating film GI_1 and a second gate insulating film GI_2) is single film, but this is merely for convenience of explanation and the present disclosure is not limited thereto. For example, each of the first gate insulating film GI_1 and the second gate insulating film GI_2 may include multiple layers.

The semiconductor memory device according to some example embodiments of the present disclosure may include memory cells including a vertical channel transistor (VCT).

Referring to FIGS. 1 to 7, the semiconductor memory device according to some example embodiments may include a first source line SL1, a second source line SL2, a first bit line BL1, a second bit line BL2, a first word line WL1, a second word line WL2, a back gate electrode BG, a first channel pattern AP1, and a second channel pattern AP2.

A substrate 100 may include, for example, silicon, silicon germanium, indium antimonide, a lead tellurium compound, indium arsenide, indium phosphide, gallium arsenide, and/or gallium antimonide.

A first lower insulating film 121 may be disposed on the substrate 100. The first lower insulating film 121 may include an insulating material.

The first source line SL1 and the second source line SL2 may be disposed on the substrate 100. For example, the first source line SL1 and the second source line SL2 may be disposed on the first lower insulating film 121.

Each of the first and second source lines SL1 and SL2 may include a portion (e.g., a source line extension SLe) extending in a first direction D1. The first direction D1 may be a horizontal direction parallel with an upper surface of the substrate 100. The first source lines SL1 and the second source lines SL2 may be alternately arranged in a second direction D2. The second direction D2 may be a horizontal direction parallel with the upper surface of the substrate 100. The first direction D1 may intersect with the second direction D2. For example, the first direction D1 may be perpendicular to the second direction D2. In some embodiments, one of the first source lines SL1 may be disposed between the second source lines SL2 adjacent to each other in the second direction D2. In some embodiment, one of the second source lines SL2 may be disposed between the first source lines SL1 adjacent to each other in the second direction D2.

Each of the first and second source lines SL1 and SL2 may include the source line extension SLe and a source line protrusion SLp. The source line protrusion SLp is connected to the source line extension SLe.

The source line extension SLe may have a line shape extending in the first direction D1. The source line protrusion SLp may protrude from the source line extension SLe in a third direction D3. The third direction D3 may be a vertical direction perpendicular to the upper surface of the substrate 100. The third direction D3 may intersect with the first direction D1 and the second direction D2. In each of the first source line SL1 and the second source line SL2, a plurality of source line protrusions SLp may be arranged in the first direction D1.

In the plurality of first source lines SL1 arranged in the second direction D2, corresponding source line protrusions SLp may be aligned in the second direction D2. For example, adjacent first source lines SL1 among the plurality of first source lines SL1 may include the source line protrusions SLp aligned in the second direction D2. One of the second source lines SL2 may be disposed between the adjacent first source lines SL1. In the plurality of second source lines SL2 arranged in the second direction D2, corresponding source line protrusions SLp may be aligned in the second direction D2. For example, adjacent second source lines SL2 among the plurality of second source lines SL2 may include the source line protrusions SLp aligned in the second direction D2. One of the first source lines SL1 may be disposed between the adjacent second source lines SL2.

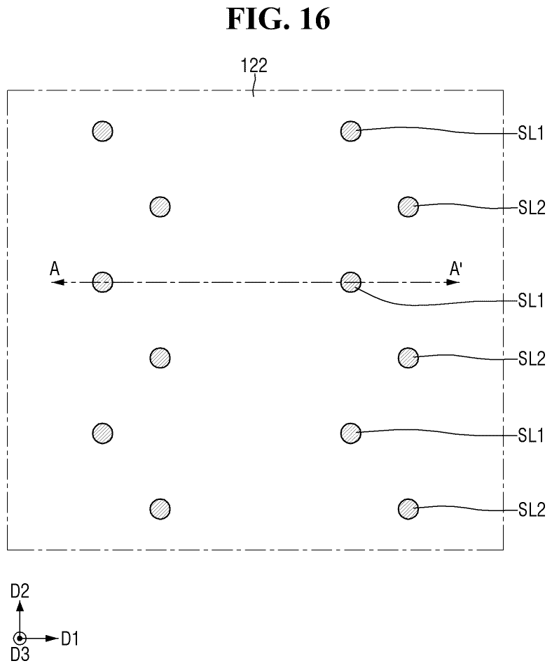

In the first source line SL1 and the second source line SL2 adjacent (e.g., closest) to each other in the second direction D2, the source line protrusion SLp included in the first source line SL1 may not be aligned with the source line protrusion SLp included in the second source line SL2 in the second direction D2. Referring to FIG. 16, in a plan view, the source line protrusion SLp included in the first source line SL1 and the source line protrusion SLp included in the second source line SL2 may be disposed in a zigzag pattern in the second direction D2.

The first source line SL1 and the second source line SL2 may include, for example, a conductive material, such as a doped semiconductor material, a conductive metal nitride, a conductive metal silicon nitride, a metal carbonitride, a conductive metal silicide, a conductive metal oxide, a two-dimensional (2D) material, a metal, and/or a metal alloy.

In the semiconductor memory device, according to some example embodiments, the two-dimensional material may include a metallic material and/or a semiconductor material. The 2D material may include, for example, a two-dimensional allotrope or a two-dimensional compound. For example, the 2D material may include graphene, molybdenum disulfide (MoS₂), molybdenum diselenide (MoSe₂), tungsten diselenide (WSe₂), and/or tungsten disulfide (WS₂), but is not limited thereto. That is, since the above-described 2D material is only listed as an example, the 2D material that may be included in the semiconductor memory device of the present disclosure is not limited by the above-described material.

The source line protrusion SLp and the source line extension SLe may form a unitary structure. A unitary structure herein may refer to a structure without a visible boundary between at least two sub-elements thereof. For example, a boundary between the source line protrusion SLp and the source line extension SLe may not be distinguished, but this is only for convenience of explanation and the present disclosure is not limited thereto. As an example, the source line protrusion SLp and the source line extension SLe may include the same material. As another example, the source line protrusion SLp may include a material different from that of the source line extension SLe.

A second lower insulating film 122 may be disposed on the first lower insulating film 121. The first source line SL1 and the second source line SL2 may be disposed in the second lower insulating film 122. The source line extensions SLe adjacent to each other in the second direction D2 may be separated by the second lower insulating film 122.

The second lower insulating film 122 may include an upper portion and a lower portion. The source line extension SLe may be disposed in the lower portion of the second lower insulating film 122. The source line protrusion SLp may be disposed in the upper portion of the second lower insulating film 122. For example, the source line protrusion SLp may be farther than the source line extension SLe from the upper surface of the substrate 100 in the third direction D3.

The second lower insulating film 122 may include an insulating material. The lower portion of the second lower insulating film 122 and the upper portion of the second lower insulating film 122 may include the same insulating material or different insulating materials. The upper portion of the second lower insulating film 122 and the lower portion of the second lower insulating film 122 may form a unitary structure. For example, there is no boundary between the lower portion of the second lower insulating film 122 and the upper portion of the second lower insulating film 122, but the present disclosure is not limited thereto.

The first channel patterns AP1 may be disposed on the first source line SL1 and the second source line SL2. The second channel patterns AP2 may be disposed on the first source line SL1 and the second source line SL2. The first channel patterns AP1 and the second channel patterns AP2 may be disposed on the second lower insulating film 122.

The first channel patterns AP1 and the second channel patterns AP2 may be alternately disposed in the first direction D1. The first channel patterns AP1 and the second channel patterns AP2 may be disposed on a pair of first and second source lines SL1 and SL2. For example, one of the first channel patterns AP1 and one of the second channel patterns AP2 may be disposed on one of the first source lines SL1 and one of the second source lines SL2 that are adjacent to each other. For example, a pair of adjacent first channel pattern AP1 and second channel pattern AP2 may overlap a pair of adjacent first source line SL1 and second source line SL2 in the third direction D3.

The first channel patterns AP1 may be spaced apart from each other in the second direction D2. The first channel patterns AP1 may be spaced apart from each other at regular intervals. The second channel patterns AP2 may be spaced apart from each other in the second direction D2. The second channel patterns AP2 may be spaced apart from each other at regular intervals. The first channel patterns AP1 and the second channel patterns AP2 may be two-dimensionally arranged in the first and second directions D1 and D2 intersecting each other.

The first channel pattern AP1 may be connected (e.g., electrically connected) to the first source line SL1 and may not be connected to (e.g., may be spaced apart from) the second source line SL2. The second channel pattern AP2 may be connected (e.g., electrically connected) to the second source line SL2 and may not be connected to (e.g., may be spaced apart from) the first source line SL1. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. When an element or layer is referred to as being “connected to”, or “coupled to” another element or layer, it may refer to a physical connection or a physical coupling. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

In some embodiments, each first source line SL1 may be electrically connected to the plurality of first channel patterns AP1 arranged in the first direction D1, and may not be electrically connected to the plurality of second channel patterns AP2 arranged in the first direction D1. Each second source line SL2 may be electrically connected to the plurality of second channel patterns AP2 arranged in the first direction D1, and may not be electrically connected to the plurality of first channel patterns AP1 arranged in the first direction D1.

The first channel pattern AP1 may be in contact with the source line protrusion SLp of the first source line SL1. The second channel pattern AP2 may be in contact with the source line protrusion SLp of the second source line SL2.

In FIGS. 6 and 7, the first channel pattern AP1 and the second channel pattern AP2 may be separated from each other. The first channel pattern API and the second channel pattern AP2 may not be connected.

The first channel pattern AP1 may include a horizontal portion AP1_H and vertical portions AP1_V1 and AP1_V2 (a first vertical portion AP1_V1 and a second vertical portion AP1_V2 of the first channel pattern AP1). The vertical portions AP1_V1 and AP1_V2 of the first channel pattern AP1 may protrude from the horizontal portion AP1_H of the first channel pattern AP1 in the third direction D3.

The horizontal portion AP1_H of the first channel pattern AP1 may be connected to the first source line SL1. The horizontal portion AP1_H of the first channel pattern AP1 may be in contact with the source line protrusion SLp of the first source line SL1. The horizontal portion AP1_H of the first channel pattern AP1 may be disposed on a plane formed in the first direction D1 and the second direction D2. In a cross-sectional view, the horizontal portion AP1_H of the first channel pattern AP1 may extend in the first direction D1 and/or the second direction D2.

The vertical portions AP1_V1 and AP1_V2 of the first channel pattern AP1 may include the first vertical portion AP1_V1 and the second vertical portion AP1_V2. The first vertical portion AP1_V1 of the first channel pattern AP1 and the second vertical portion AP1_V2 of the first channel pattern AP1 may protrude from the horizontal portion AP1_H of the first channel pattern AP1 in the third direction D3. The first vertical portion AP1_V1 of the first channel pattern AP1 may be directly connected to the second vertical portion AP1_V2 of the first channel pattern AP1. In a plan view, the first vertical portion AP1_V1 of the first channel pattern AP1 may extend in the second direction D2. The second vertical portion AP1_V2 of the first channel pattern AP1 may protrude from the first vertical portion AP1_V1 of the first channel pattern AP1 in the first direction D1. For example, a shape of the first channel pattern AP1 in a plan view may be a shape such as “[”.

The second channel pattern AP2 may include a horizontal portion AP2_H and vertical portions AP2_V1 and AP2_V2 (a first vertical portion AP2_V1 and a second vertical portion AP2_V2 of the second channel pattern AP2). The vertical portions AP2_V1 and AP2_V2 of the second channel pattern AP2 may protrude from the horizontal portion AP2_H of the second channel pattern AP2 in the third direction D3.

Although not shown, the horizontal portion AP2_H of the second channel pattern AP2 may be connected to the second source line SL2. The horizontal portion AP2_H of the second channel pattern AP2 may be in contact with the source line protrusion SLp of the second source line SL2. The horizontal portion AP2_H of the second channel pattern AP2 may be disposed on a plane formed in the first direction D1 and the second direction D2. In a cross-sectional view, the horizontal portion AP2_H of the second channel pattern AP2 may extend in the first direction D1 and/or the second direction D2.

The vertical portions AP2_V1 and AP2_V2 of the second channel pattern AP2 may include the first vertical portion AP2_V1 and the second vertical portion AP2_V2. The first vertical portion AP2_V1 of the second channel pattern AP2 and the second vertical portion AP2_V2 of the second channel pattern AP2 may protrude from the horizontal portion AP2_H of the second channel pattern AP2 in the third direction D3. The first vertical portion AP2_V1 of the second channel pattern AP2 may be directly connected to the second vertical portion AP2_V2 of the second channel pattern AP2. In a plan view, the first vertical portion AP2_V1 of the second channel pattern AP2 may extend in the second direction D2. The second vertical portion AP2_V2 of the second channel pattern AP2 may protrude from the first vertical portion AP2_V1 of the second channel pattern AP2 in the first direction D1. For example, a shape of the second channel pattern AP2 in a plan view may be a shape such as “]”. In some embodiments, the first channel pattern AP1 may be a mirror-image of the second channel pattern AP2 in a plan view and/or in a cross-sectional view.

The first vertical portion AP1_V1 of the first channel pattern AP1 and the first vertical portion AP2_V1 of the second channel pattern AP2 may include a first sidewall AP_SW1 and a second sidewall AP_SW2 opposite in the first direction D1, respectively. For example, the first sidewall AP_SW1 may be an outer sidewall of the first channel pattern AP1 and/or the second channel pattern AP2. The second sidewall AP_SW2 may be an inner sidewall of the first channel pattern AP1 and/or the second channel pattern AP2. The second sidewall AP_SW2 of the first vertical portion AP1_V1 of the first channel pattern AP1 may face the second sidewall AP_SW2 of the first vertical portion AP2_V1 of the second channel pattern AP2.

The first channel pattern AP1 and/or the second channel pattern AP2 may include, for example, polycrystalline silicon (polysilicon), polycrystalline silicon germanium, and/or polycrystalline germanium.

The first channel pattern AP1 and/or the second channel pattern AP2 may include, for example, an oxide semiconductor material. The first channel pattern AP1 and/or the second channel pattern AP2 may include, for example, metal oxide. In some embodiments, the first channel pattern AP1 and/or the second channel pattern AP2 may include amorphous metal oxide films. In some embodiments, the first channel pattern AP1 and/or the second channel pattern AP2 may include polycrystalline metal oxide films. The first channel pattern AP1 and/or the second channel pattern AP2 may include a combination of an amorphous metal oxide film and a polycrystalline metal oxide film. The first channel pattern AP1 and/or the second channel pattern AP2 may include c-axis aligned crystalline (CAAC) metal oxide films.

The first channel pattern AP1 and/or the second channel pattern AP2 may include, for example, indium oxide, tin oxide, zinc oxide, In—Zn oxide (IZO), Sn—Zn oxide, Al—Zn oxide, Zn—Mg oxide, Sn—Mg oxide, In—Mg oxide, In—Ga oxide (IGO), In—Ga—Zn oxide (IGZO), In—Al—Zn oxide, In—Sn—Zn oxide, Sn—Ga—Zn oxide, Al—Ga—Zn oxide, Sn—Al—Zn oxide, In—Hf—Zn oxide, In—La—Zn oxide, In—Ce—Zn oxide, In—Pr—Zn oxide, In—Nd—Zn oxide, In—Sm—Zn oxide, In—Eu—Zn oxide, In—Gd—Zn oxide, In—Tb—Zn oxide, In—Dy—Zn oxide, In—Ho—Zn oxide, In—Er—Zn oxide, In—Tm—Zn oxide, In—Yb—Zn oxide, In—Lu—Zn oxide, In—Sn—Ga—Zn oxide, In—Hf—Ga—Zn oxide, In—Al—Ga—Zn oxide, In—Sn—Al—Zn oxide, In—Sn—Hf—Zn oxide, and/or In—Hf—Al—Zn oxide, but are not limited thereto.

Here, the In—Ga—Zn oxide may refer to an oxide having In, Ga, and Zn as main components, but does not indicate a ratio of In, Ga, and Zn. That is, taking indium gallium zinc oxide (IGZO) as an example, the first channel pattern AP1 and/or the second channel pattern AP2 may include indium gallium zinc oxide (IGZO, InₓGa_{y}Zn_{z}O). IGZO (In:Ga:Zn=1:1:1) containing indium, gallium, and zinc in the same ratio may be In—Ga—Zn oxide. Ga-rich IGZO may have a higher gallium ratio than IGZO (In:Ga:Zn=1:1:1), and may have a lower indium ratio than IGZO (In:Ga:Zn=1:1:1). Ga-rich IGZO may also be the In—Ga—Zn oxide. In addition, In-rich IGZO may have a higher indium ratio than IGZO (In:Ga:Zn=1:1:1), and may have a lower gallium ratio than IGZO (In:Ga:Zn=1:1:1). In-rich IGZO may also be the In—Ga—Zn oxide.

A first word line WL1 and a second word line WL2 may be disposed on the first source line SL1 and the second source line SL2. For example, the first word line WL1 may be disposed on the first source line SL1 and the second source line SL2. The second sord line WL2 may be disposed on the first source line SL1 and the second source line SL2. Each of the first word line WL1 and the second word line WL2 may extend in the second direction D2.

The first word line WL1 and the second word line WL2 may be spaced apart from the first source line SL1 and the second source line SL2 in the third direction D3. Each of the first word line WL1 and the second word line WL2 may intersect the first source line SL1 and the second source line SL2.

The first word lines WL1 and the second word lines WL2 may be alternately arranged in the first direction D1. The first word line WL1 may be spaced apart from the second word line WL2 in the first direction D1.

The first word line WL1 may be disposed on the first channel pattern AP1. The first word line WL1 may be disposed on the plurality of first channel patterns AP1 arranged in the second direction D2. The first word line WL1 may be disposed on the horizontal portion AP1_H of the first channel pattern AP1. The first word line WL1 may be disposed on the second sidewall AP_SW2 of the first vertical portion AP1_V1 of the first channel pattern AP1.

The second word line WL2 may be disposed on the second channel pattern AP2. The second word line WL2 may be disposed on the plurality of second channel patterns AP2 arranged in the second direction D2. The second word line WL2 may be disposed on the horizontal portion AP2_H of the second channel pattern AP2. The second word line WL2 may be disposed on the second sidewall AP_SW2 of the first vertical portion AP2_V1 of the second channel pattern AP2.

The first channel pattern AP1 may be closer to the first word line WL1 than to the second word line WL2. The second channel pattern AP2 may be closer to the second word line WL2 than to the first word line WL1.

The first word line WL1 and the second word line WL2 may be disposed between the first channel pattern AP1 and the second channel pattern AP2. For example, the first word line WL1 and the second word line WL2 may be disposed between adjacent (e.g., a pair of) first channel pattern AP1 and second channel pattern AP2. Since the first word line WL1 and the second word line WL2 are alternately disposed in the first direction D1 and the first channel pattern AP1 and the second channel pattern AP2 are alternately disposed in the first direction D1, the first channel pattern AP1 and the second channel pattern AP2 may be disposed between the first word line WL1 and the second word line WL2.

The first word line WL1 may include a horizontal portion WL1_H and a vertical portion WL1_V. The vertical portion WL1_V of the first word line WL1 may protrude from the horizontal portion WL1_H of the first word line WL1 in the third direction D3.

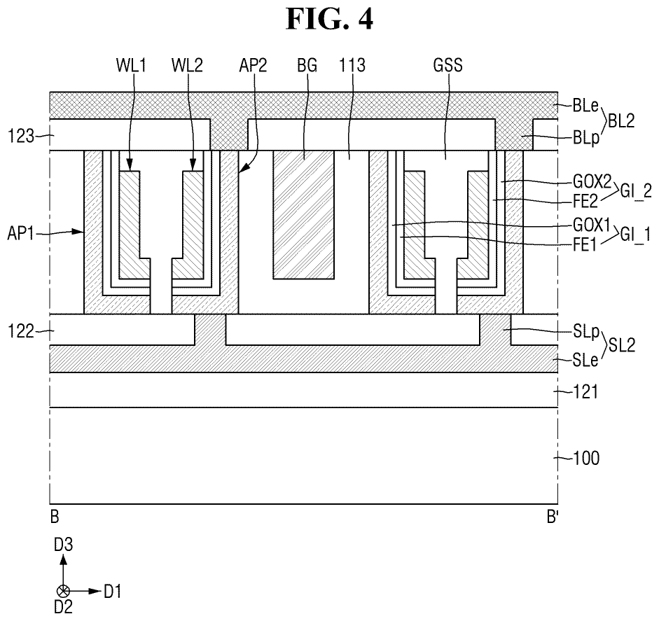

The second word line WL2 may include a horizontal portion WL2_H and a vertical portion WL2_V. The vertical portion WL2_V of the second word line WL2 may protrude from the horizontal portion WL2_H of the second word line WL2 in the third direction D3. In the cross-sectional views of FIGS. 3 and 4, the first word line WL1 and the second word line WL2 may have an “L” shape. In some embodiments, the first word line WL1 may be a mirror-image of the second word line WL2 in a cross-sectional view.

Each of the first word line WL1 and the second word line WL2 may include first and second surfaces WL_S1 and WL_S2 opposite to each other in the third direction D3. The second surface WL_S2 of the first word line WL1 may face the horizontal portion AP1_H of the first channel pattern AP1. The second surface WL_S2 of the second word line WL2 may face the horizontal portion AP2_H of the second channel pattern AP2.

Each of the vertical portion WL1_V of the first word line WL1 and the vertical portion WL2_V of the second word line WL2 may include the first surface WL_S1 of the corresponding word line. Each of the horizontal portion WL1_H of the first word line WL1 and the horizontal portion WL2_H of the second word line WL2 may include the second surface WL_S2 of the corresponding word line.

With respect to an upper surface of the second lower insulating film 122, the first surfaces WL_S1 of the first and second word lines WL1 and WL2 may be lower than the uppermost portions of the first vertical portions AP1_V1 and AP2_V1 of the first and second channel patterns AP1 and AP2. The uppermost portion of the first channel pattern AP1 may be the uppermost portion of the first vertical portion AP1_V1 of the first channel pattern AP1, and the uppermost portion of the second channel pattern AP2 may be the uppermost portion of the first vertical portion AP2_V1 of the second channel pattern AP2.

It is illustrated in FIG. 6 that the first surfaces WL_S1 of the first and second word lines WL1 and WL2 are flat, but the present disclosure is not limited thereto. Unlike illustrated, as an example, the first surfaces WL_S1 of the first and second word lines WL1 and WL2 may be convexly rounded. As another example, the first surfaces WL_S1 of the first and second word lines WL1 and WL2 may be concavely rounded.

The first word line WL1 and the second word line WL2 may include a conductive material, for example, a doped polysilicon, a conductive metal nitride, a conductive metal silicon nitride, a metal carbonitride, a conductive metal silicide, a conductive metal oxide, a two-dimensional material, and/or a metal.

The first gate insulating film GI_1 may be disposed between the first word line WL1 and the first channel pattern AP1. The first gate insulating film GI_1 may extend along the horizontal portion AP1_H of the first channel pattern AP1, the first vertical portion AP1_V1 of the first channel pattern AP1, and the second vertical portion AP1_V2 of the first channel pattern AP1.

The second gate insulating film GI_2 may be disposed between the second word line WL2 and the second channel pattern AP2. The second gate insulating film GI_2 may extend along the horizontal portion AP2_H of the second channel pattern AP2, the first vertical portion AP2_V1 of the second channel pattern AP2, and the second vertical portion AP2_V2 of the second channel pattern AP2. In some embodiments, the first gate insulating film GI_1 may be separated from the second gate insulating film GI_2.

A portion of the first gate insulating film GI_1 and a portion of the second gate insulating film GI_2 may more protrude in the third direction D3 than the first surfaces WL_S1 of the word lines WL1 and WL2. For example, with respect to the upper surface of the second lower insulating film 122, upper surfaces of the first gate insulating film GI_1 and the second gate insulating film GI_2 may be disposed higher than the first surfaces WL_S1 of the first and second word lines WL1 and WL2.

The first gate insulating film GI_1 may include a first gate insulating oxide film GOX1 and a first ferroelectric material film FE1. The first gate insulating oxide film GOX1 may be disposed between the first channel pattern AP1 and the first ferroelectric material film FE1. The second gate insulating film GI_2 may include a second gate insulating oxide film GOX2 and a second ferroelectric material film FE2. The second gate insulating oxide film GOX2 may be disposed between the second channel pattern AP2 and the second ferroelectric material film FE2.

In FIG. 2, the semiconductor memory device according to some example embodiments may include a first sub-memory cell area MC_SB1 and a second sub-memory cell area MC_SB2 spaced apart from each other in the second direction D2. Each of the first sub-memory cell area MC_SB1 and the second sub-memory cell area MC_SB2 may be defined between a pair of first word line WL1 and second word line WL2 and a pair of first channel pattern AP1 and second channel pattern AP2. The first sub-memory cell area MC_SB1 and the second sub-memory cell area MC_SB2 may be disposed between back gate electrodes BG adjacent to each other.

In the semiconductor memory device according to some example embodiments, the first gate insulating film GI_1 included in the first sub-memory cell area MC_SB1 may not be connected to the first gate insulating film GI_1 included in the second sub-memory cell area MC_SB2. The second gate insulating film GI_2 included in the first sub-memory cell area MC_SB1 may not be connected to the second gate insulating film GI_2 included in the second sub-memory cell area MC_SB2.

The first gate insulating film GI_1 included in the first sub-memory cell area MC_SB1 may be separated from the first gate insulating film GI_1 included in the second sub-memory cell area MC_SB2. The second gate insulating film GI_2 included in the first sub-memory cell area MC_SB1 may be separated from the second gate insulating film GI_2 included in the second sub-memory cell area MC_SB2.

The first gate insulating oxide film GOX1 and the second gate insulating oxide film GOX2 may include silicon oxide. For example, the first gate insulating oxide film GOX1 and the second gate insulating oxide film GOX2 may include silicon oxide films.

The first ferroelectric material film FE1 and the second ferroelectric material film FE2 may include a ferroelectric material. For example, the first ferroelectric material film FE1 and the second ferroelectric material film FE2 may be formed of a ferroelectric material.

The first ferroelectric material film FE1 and the second ferroelectric material film FE2 may include, for example, hafnium oxide, hafnium zirconium oxide, barium strontium titanium oxide, barium titanium oxide, and/or lead zirconium titanium oxide. Here, as an example, the hafnium zirconium oxide may be a material obtained by doping hafnium oxide with zirconium (Zr). The hafnium zirconium oxide may also be a compound of hafnium (Hf), zirconium (Zr), and oxygen (O). The above-described ferroelectric material is only an example, and the technical scope of the present disclosure is not limited thereto.

The first ferroelectric material film FE1 and the second ferroelectric material film FE2 may further include a doped dopant. For example, the dopant may include, for example, aluminum (Al), titanium (Ti), niobium (Nb), lanthanum (La), yttrium (Y), magnesium (Mg), silicon (Si), calcium (Ca), cerium (Cc), dysprosium (Dy), erbium (Er), gadolinium (Gd), germanium (Ge), scandium (Sc), strontium (Sr), and/or tin (Sn). Depending on which ferroelectric material the first ferroelectric material film FE1 and the second ferroelectric material film FE2 include, the types of dopants included in the first ferroelectric material film FE1 and the second ferroelectric material film FE2 may be different.

When the first ferroelectric material film FE1 and the second ferroelectric material film FE2 include hafnium oxide, the dopants included in the first ferroelectric material film FE1 and the second ferroelectric material film FE2 may include, for example, gadolinium (Gd), silicon (Si), zirconium (Zr), aluminum (Al), and/or yttrium (Y).

When the dopant is aluminum (Al), the first ferroelectric material film FE1 and the second ferroelectric material film FE2 may include, for example, 3 to 8 at % (atomic %) of aluminum. Here, a ratio of the dopant may be a ratio of aluminum to the sum of hafnium and aluminum. When the dopant is silicon (Si), the first ferroelectric material film FE1 and the second ferroelectric material film FE2 may include, for example, 2 to 10 at % of silicon. When the dopant is yttrium (Y), the first ferroelectric material film FE1 and the second ferroelectric material film FE2 may include, for example, 2 to 10 at % of yttrium. When the dopant is gadolinium (Gd), the first ferroelectric material film FE1 and the second ferroelectric material film FE2 may include, for example, 1 to 7 at % of gadolinium. When the dopant is zirconium (Zr), the first ferroelectric material film FE1 and the second ferroelectric material film FE2 may include, for example, 50 to 80 at % of zirconium.

The first ferroelectric material film FE1 and the second ferroelectric material film FE2 may have thicknesses having ferroelectric characteristics. Thicknesses of the first ferroelectric material film FE1 and the second ferroelectric material film FE2 may be, for example, 0.5 to 10 nm, but are not limited thereto. Since a critical thickness representing ferroelectric characteristics may vary for each ferroelectric material, the thicknesses of the first ferroelectric material film FE1 and the second ferroelectric material film FE2 may vary depending on the ferroelectric material thereof.

A gate separation pattern GSS may be disposed on the second lower insulating film 122, the first source line SL1, and the second source line SL2. The gate separation pattern GSS may be disposed on the first channel pattern AP1, the second channel pattern AP2, the first word line WL1, and the second word line WL2.

In the semiconductor memory device according to some example embodiments, the gate separation pattern GSS may be in contact with the first channel pattern AP1 and the second channel pattern AP2. The gate separation pattern GSS may be in contact with the horizontal portion AP1_H of the first channel pattern AP1 and the horizontal portion AP2_H of the second channel pattern AP2. The gate separation pattern GSS may separate the first channel pattern AP1 and the second channel pattern AP2.

The gate separation pattern GSS may be disposed between the first word line WL1 and the second word line WL2 adjacent to each other in the first direction D1. The first word line WL1 and the second word line WL2 may be separated by the gate separation pattern GSS. The gate separation pattern GSS may extend in the second direction D2 between the first word line WL1 and the second word line WL2.

The first word line WL1 may be disposed between the gate separation pattern GSS and the first channel pattern AP1. The second word line WL2 may be disposed between the gate separation pattern GSS and the second channel pattern AP2.

The gate separation pattern GSS may include a horizontal portion GSS_H and a protrusion GSS_P. The horizontal portion GSS_H of the gate separation pattern GSS may be disposed on the first surfaces WL_S1 of the word lines WL1 and WL2. The horizontal portion GSS_H of the gate separation pattern GSS may overlap (e.g., cover) the first surfaces WL_S1 of the word lines WL1 and WL2.

The protrusion GSS_P of the gate separation pattern GSS may protrude from the horizontal portion GSS_H of the gate separation pattern GSS toward the source lines SL1 or SL2 in the third direction D3. A width of the horizontal portion GSS_H of the gate separation pattern GSS in the first direction D1 may be greater than a width of the protrusion GSS_P of the gate separation pattern GSS in the first direction D1. In a cross-sectional view, the gate separation pattern GSS may have a “T” shape.

The protrusion GSS_P of the gate separation pattern GSS may be disposed between the first word line WL1 and the second word line WL2 adjacent to each other in the first direction D1. In the semiconductor memory device according to some example embodiments, the first channel pattern AP1 and the second channel pattern AP2 may be separated by the protrusion GSS_P of the gate separation pattern GSS. The horizontal portion AP1_H of the first channel pattern AP1 and the horizontal portion AP2_H of the second channel pattern AP2 may be in contact with the protrusion GSS_P of the gate separation pattern GSS.

The gate separation pattern GSS may include an insulating material. It is illustrated that the gate separation pattern GSS is a single film, but this is only for convenience of explanation and the present disclosure is not limited thereto.

The back gate electrode BG may be disposed on the first source line SL1 and the second source line SL2. The back gate electrodes BG may extend in the second direction D2. The back gate electrodes BG may be spaced apart from each other in the first direction D1. The back gate electrodes BG may be spaced apart from each other at regular intervals.

Each back gate electrode BG may be disposed between the first channel pattern AP1 and the second channel pattern AP2 adjacent to each other in the first direction D1. The first channel pattern AP1 may be disposed on one side of each back gate electrode BG, and the second channel pattern AP2 may be disposed on the other side of each back gate electrode BG in the first direction D1.

Each back gate electrode BG may be disposed between the first word line WL1 and the second word line WL2 adjacent to each other in the first direction D1. The first word line WL1 may be disposed on one side of each back gate electrode BG, and the second word line WL2 may be disposed on the other side of each back gate electrode BG in the first direction D1.

In other words, a pair of first and second word lines WL1 and WL2 may be disposed between the back gate electrodes BG adjacent to each other in the first direction D1. The first channel pattern AP1 and the second channel pattern AP2 (e.g., a pair of the first channel pattern AP1 and the second channel pattern AP2) may be disposed between the back gate electrodes BG adjacent to each other in the first direction D1.

The plurality of first channel patterns AP1 aligned in the second direction D2 may be disposed between the first word line WL1 (e.g., the closest first word line WL1 in the first direction D1) and the back gate electrode BG (e.g., the closest back gate electrode BG in the first direction D1). The plurality of second channel patterns AP2 aligned in the second direction D2 may be disposed between the second word line WL2 (e.g., the closest second word line WL2 in the first direction D1) and the back gate electrode BG (e.g., the closest back gate electrode BG in the first direction D1).

The back gate electrode BG may be disposed on the first sidewall AP_SW1 of the first vertical portion AP1_V1 of the first channel pattern AP1. The back gate electrode BG may be disposed on the first sidewall AP_SW1 of the first vertical portion AP2_V1 of the second channel pattern AP2. The first sidewall AP_SW1 of the first vertical portion AP1_V1 of the first channel pattern AP1 and the first sidewall AP_SW1 of the first vertical portion AP2_V1 of the second channel pattern AP2 may face the back gate electrode BG.

The back gate electrode BG may be disposed on the first sidewalls AP_SW1 of the first vertical portions AP1_V1 and AP2_V1 of the channel patterns AP1 and AP2. The word lines WL1 and WL2 may be disposed on the second sidewalls AP_SW2 of the first vertical portions AP1_V1 and AP2_V1 of the channel patterns AP1 and AP2.

The back gate electrode BG may include a conductive material, for example, a doped polysilicon, a conductive metal nitride, a conductive metal silicon nitride, a metal carbonitride, a conductive metal silicide, a conductive metal oxide, a two-dimensional material, and/or a metal. During operation of the semiconductor memory device, a voltage may be applied to the back gate electrode BG to adjust a threshold voltage of the vertical channel transistor. As the threshold voltage of the vertical channel transistor is adjusted, degradation of leakage current characteristics may be improved (e.g., reduced or prevented).

A back gate insulating film 113 may be disposed between the back gate electrode BG and the first channel pattern AP1 and between the back gate electrode BG and the second channel pattern AP2. The back gate insulating film 113 may be disposed between the back gate electrode BG and the second lower insulating film 122. The back gate insulating film 113 may extend along sidewalls and a lower surface of the back gate electrode BG.

The back gate insulating film 113 may include, for example, silicon oxide. For example, the back gate insulating film 113 may include a silicon oxide film.

A thickness t1 of the back gate insulating film 113 in the first direction D1 may be different from a thickness t2 of the first gate insulating oxide film GOX1 and a thickness t2 of the second gate insulating oxide film GOX2 in the first direction D1. For example, the thickness t1 of the back gate insulating film 113 in the first direction D1 may be greater than the thickness t2 of the first gate insulating oxide film GOX1 and/or the thickness t2 of the second gate insulating oxide film GOX2 in the first direction D1.

Here, the thickness t1 of the back gate insulating film 113 in the first direction D1 may be a thickness between the back gate electrode BG and the first channel pattern AP1 and/or between a thickness between the back gate electrode BG and the second channel pattern AP2 in the first direction D1. The thickness t2 of the first gate insulating oxide film GOX1 in the first direction D1 may be a thickness between the first ferroelectric material film FE1 and the first vertical portion AP1_V1 of the first channel pattern AP1. The thickness t2 of the second gate insulating oxide film GOX2 in the first direction D1 may be a thickness between the second ferroelectric material film FE2 and the first vertical portion AP2_V1 of the second pattern AP2.

As the thickness t1 is greater than the thickness t2, a memory window between a read operation and a write operation of the semiconductor memory device may increase.

A first bit line BL1 and a second bit line BL2 may be disposed on the first channel patterns AP1 and the second channel patterns AP2. The first bit line BL1 and the second bit line BL2 may be disposed on the first word lines WL1 and the second word lines WL2.

Each of the first bit line BL1 and the second bit line BL2 may extend in the first direction D1. The first bit lines BL1 and the second bit lines BL2 may be alternately arranged in the second direction D2. The first bit line BL1 may be disposed between the second bit lines BL2 adjacent to each other in the second direction D2. The second bit line BL2 may be disposed between the first bit lines BL1 adjacent to each other in the second direction D2.

Each first bit line BL1 may be disposed on a corresponding first source line SL1. Each second bit line BL2 may be disposed on a corresponding second source line SL2.

Each of the first bit line BL1 and the second bit line BL2 may include a bit line extension BLe and a plurality of bit line protrusions BLp. Each bit line protrusion BLp may be connected to the bit line extension BLe.

The bit line extension BLe may have a line shape extending in the first direction D1. Each bit line protrusion BLp may protrude from the bit line extension BLe in the third direction D3. In each of the first bit line BL1 and the second bit line BL2, the plurality of bit line protrusions BLp may be arranged in the first direction D1. For example, the first bit line BL1 may include the plurality of bit line protrusions BLp arranged in the first direction D1. For example, the second bit line BL2 may include the plurality of bit line protrusions BLp arranged in the first direction D1.

In the plurality of first bit lines BL1 arranged in the second direction D2, corresponding bit line protrusions BLp may be aligned in the second direction D2. For example, adjacent first bit lines BL1 among the plurality of first bit lines BL1 may include the bit line protrusions BLp aligned in the second direction D2. One of the second bit lines BL2 may be disposed between the adjacent first bit lines BL1. In the plurality of second bit lines BL2 arranged in the second direction D2, corresponding bit line protrusions BLp may be aligned in the second direction D2. For example, adjacent second bit lines BL2 among the plurality of second bit lines BL2 may include the bit line protrusions BLp aligned in the second direction D2. One of the first bit lines BL1 may be disposed between the adjacent second bit lines BL2.

In the first bit line BL1 and the second bit line BL2 closest to each other in the second direction D2, the bit line protrusion BLp included in the first bit line BL1 may not be aligned with the bit line protrusion BLp included in the second bit line BL2 in the second direction D2. In a plan view, the bit line protrusion BLp included in the first bit line BL1 and the bit line protrusion BLp included in the second bit line BL2 may be arranged in a zigzag shape in the second direction D2.

The first channel pattern AP1 may be connected (e.g., electrically connected) to the first bit line BL1 and may not be connected to (e.g., may be spaced apart from) the second bit line BL2. The second channel pattern AP2 may be connected (e.g., electrically connected) to the second bit line BL2 and may not be connected to (e.g., may be spaced apart from) the first bit line BL1.

In other words, each first bit line BL1 may be electrically connected to the plurality of first channel patterns AP1 arranged in the first direction D1, and may not be electrically connected to the plurality of second channel patterns AP2 arranged in the first direction D1. Each second bit line BL2 may be electrically connected to the plurality of second channel patterns AP2 arranged in the first direction D1, and may not be electrically connected to the plurality of first channel patterns AP1 arranged in the first direction D1.

The first channel pattern AP1 may be in contact with the bit line protrusion BLp of the first bit line BL1 and be connected to the first bit line BL1. The second channel pattern AP2 may be in contact with the bit line protrusion BLp of the second bit line BL2 and be connected to the second bit line BL2.

The first bit line BL1 and the second bit line BL2 may include a conductive material, for example, a doped semiconductor material, a conductive metal nitride, a conductive metal silicon nitride, a metal carbonitride, a conductive metal silicide, a conductive metal oxide, a two-dimensional material, a metal, and/or a metal alloy. The bit line protrusion BLp and the bit line extension Ble may for a unitary structure. For example, a boundary between the bit line protrusion BLp and the bit line extension BLe may not be distinguished, but this is only for convenience of explanation and the present disclosure is not limited thereto.

Unlike described above, the first bit line BL1 may be connected to the second channel pattern AP2 and may not be connected to the first channel pattern AP1. The second bit line BL2 may be connected to the first channel pattern AP1 and may not be connected to the second channel pattern AP2.

A third lower insulating film 123 may be disposed on the channel patterns AP1 and AP2, the back gate electrodes BG, and the word lines WL1 and WL2. The first bit line BL1 and the second bit line BL2 may be disposed in the third lower insulating film 123. The bit line extensions BLe adjacent to each other in the second direction D2 may be separated by the third lower insulating film 123. The third lower insulating film 123 may include an insulating material.

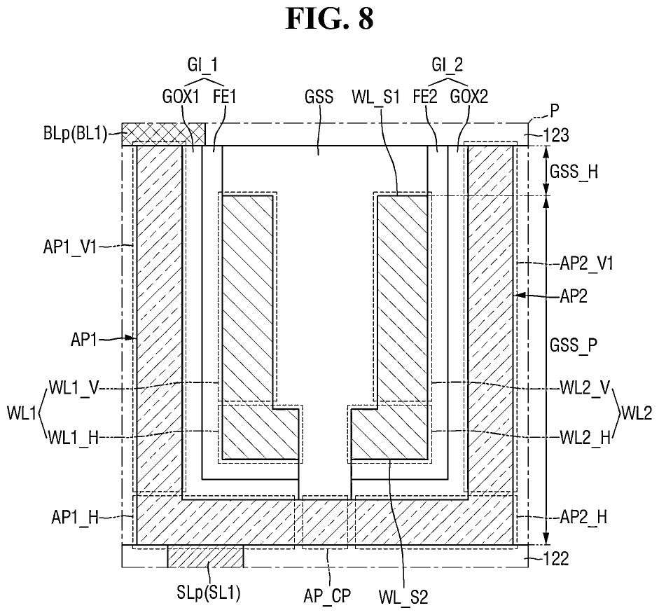

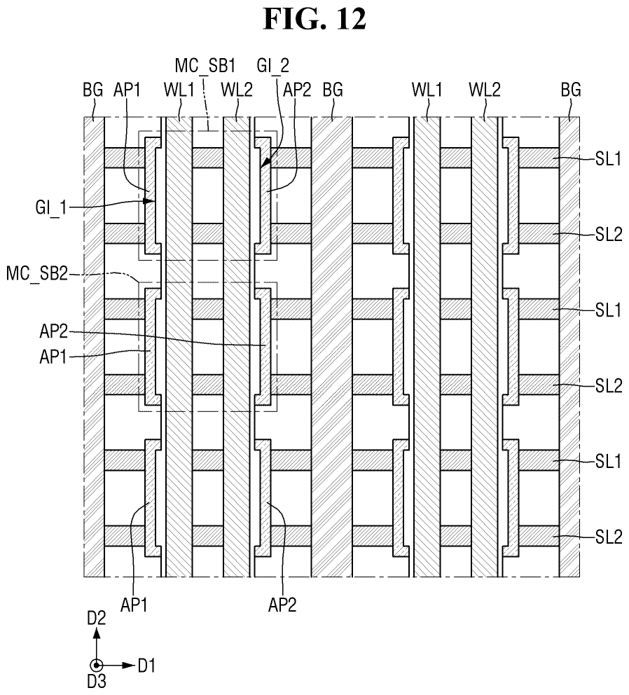

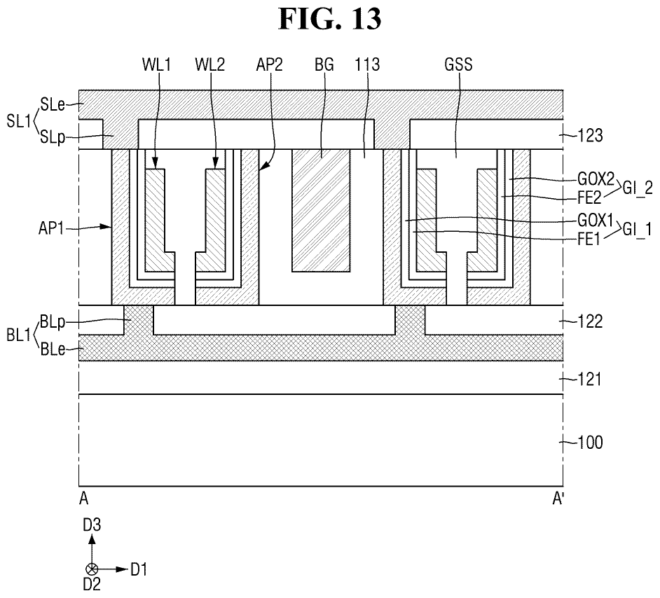

FIGS. 8 to 11 are cross-sectional views for each describing a semiconductor device according to some example embodiments. FIG. 12 is a plan view for describing a semiconductor memory device according to some example embodiments. FIG. 13 is a cross-sectional view for describing a semiconductor memory device according to some example embodiments. For convenience of explanation, points different from those described with reference to FIGS. 1 to 7 will be mainly described.

For reference, FIGS. 8 to 11 are enlarged views of part P of FIG. 3. FIG. 12 illustrates a plan view of the semiconductor memory device without bit lines.

Referring to FIGS. 8 to 10, in the semiconductor memory device according to some example embodiments, the first channel pattern AP1 and the second channel pattern AP2 the closest (e.g., adjacent) to each other (e.g., a pair of the first channel pattern AP1 and the second channel pattern AP2) may be connected by a connection channel pattern AP_CP.

The connection channel pattern AP_CP may be directly connected to the first channel pattern AP1 and the second channel pattern AP2. The connection channel pattern AP_CP may be disposed on the second lower insulating film 122. The connection channel pattern AP_CP may include the same material as the first channel pattern AP1 and the second channel pattern AP2.

With respect to the first word line WL1 and the second word line WL2, the first channel pattern AP1, the second channel pattern AP2, and the connection channel pattern AP_CP may be distinguished. The first word line WL1 will be described as an example. The first word line WL1 may include an inner sidewall facing the first vertical portion AP1_V1 of the first channel pattern AP1 and an outer sidewall having an “L” shape. A boundary between the first channel pattern AP1 and the connection channel pattern AP_CP may be an extension line in which the outer sidewall of the first word line WL1 included in the horizontal portion WL1_H of the first word line WL1 extends in the third direction D3. For example, the boundary between the first channel pattern AP1 and the connection channel pattern AP_CP may be aligned with the outer sidewall of the horizontal portion WL1_H of the first word line WL1 in the third direction D3.

The gate separation pattern GSS may be disposed on the connection channel pattern AP_CP. The gate separation pattern GSS may not separate the first channel pattern AP1 and the second channel pattern AP2.

In FIG. 8, the first gate insulating film GI_1 may not be connected to the second gate insulating film GI_2. The first gate insulating film GI_1 and the second gate insulating film GI_2 may be separated by the gate separation pattern GSS.

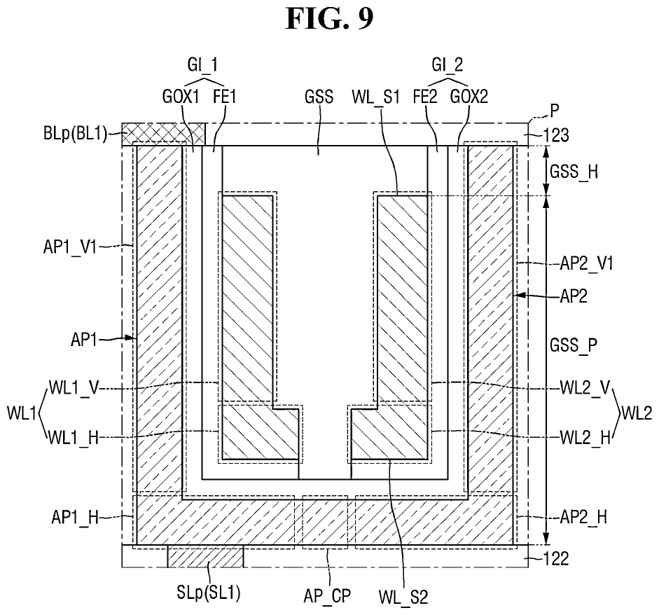

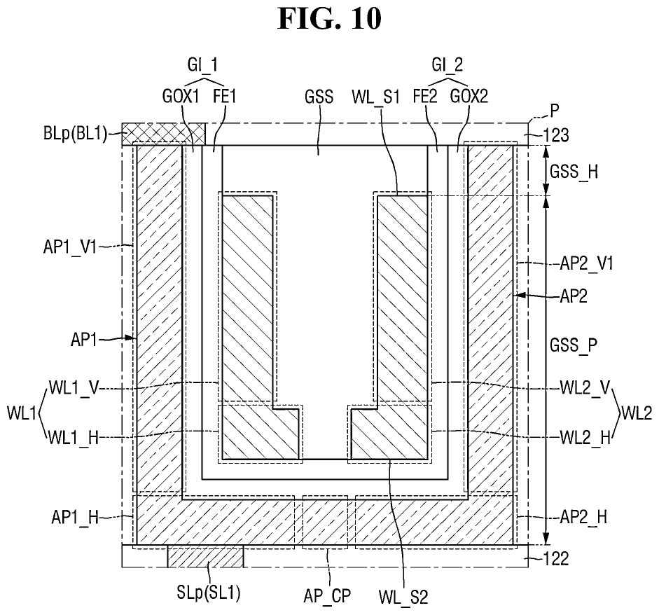

In FIGS. 9 and 10, the first gate insulating film GI_1 may be connected to the second gate insulating film GI_2.

In FIG. 9, the first gate insulating oxide film GOX1 included in the first gate insulating film GI_1 may be connected to the second gate insulating oxide film GOX2 included in the second gate insulating film GI_2. However, the first ferroelectric material film FE1 included in the first gate insulating film GI_1 may be separated from the second ferroelectric material film FE2 included in the second gate insulating film GI_2.

In FIG. 10, the first gate insulating oxide film GOX1 and the first ferroelectric material film FE1 may be connected to the second gate insulating oxide film GOX2 and the second ferroelectric material film FE2, respectively. The gate separation pattern GSS may not separate the first gate insulating film GI_1 and the second gate insulating film GI_2.

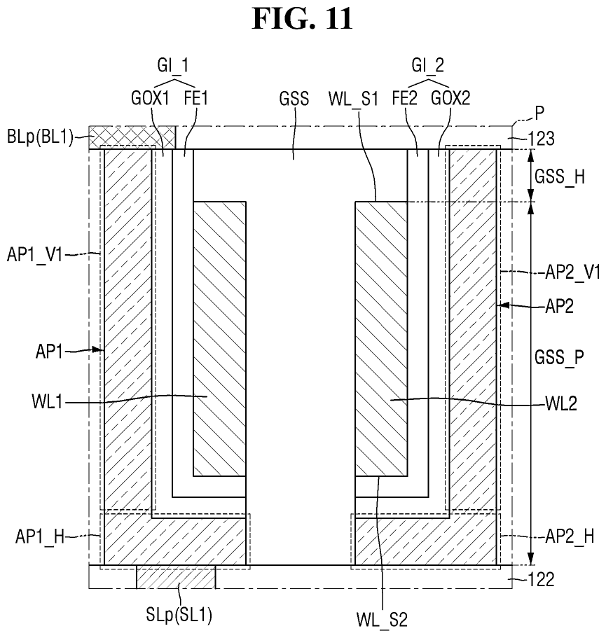

Referring to FIG. 11, in the semiconductor memory device according to some example embodiments, the first word line WL1 and the second word line WL2 may not have an “L” shape in a cross-sectional view.

For example, the first word line WL1 and the second word line WL2 may have an “I” shape.

Referring to FIG. 12, in the semiconductor memory device according to some example embodiments, the first gate insulating film GI_1 included in the first sub-memory cell area MC_SB1 may be connected to the first gate insulating film GI_1 included in the second sub-memory cell area MC_SB2.

The second gate insulating film GI_2 included in the first sub-memory cell area MC_SB1 may be connected to the second gate insulating film GI_2 included in the second sub-memory cell area MC_SB2.

In some embodiments, the first gate insulating film GI_1 included in the first sub-memory cell area MC_SB1 may be connected to the second gate insulating film GI_2 included in the second sub-memory cell area MC_SB2 by the first ferroelectric material film (FE1 in FIGS. 3 and 4).

In some embodiments, the first gate insulating film GI_1 included in the first sub-memory cell area MC_SB1 may be connected to the second gate insulating film GI_2 included in the second sub-memory cell area MC_SB2 by the first gate insulating oxide film GOX1 and the first ferroelectric material film FE1.

Referring to FIG. 13, in the semiconductor memory device according to some example embodiments, the first bit line BL1 may be disposed between the substrate 100 and the first channel pattern AP1, and between the substrate 100 and the second channel pattern AP2.

The first bit line BL1 may be disposed in the second lower insulating film 122. The first source line SL1 may be disposed in the third lower insulating film 123.

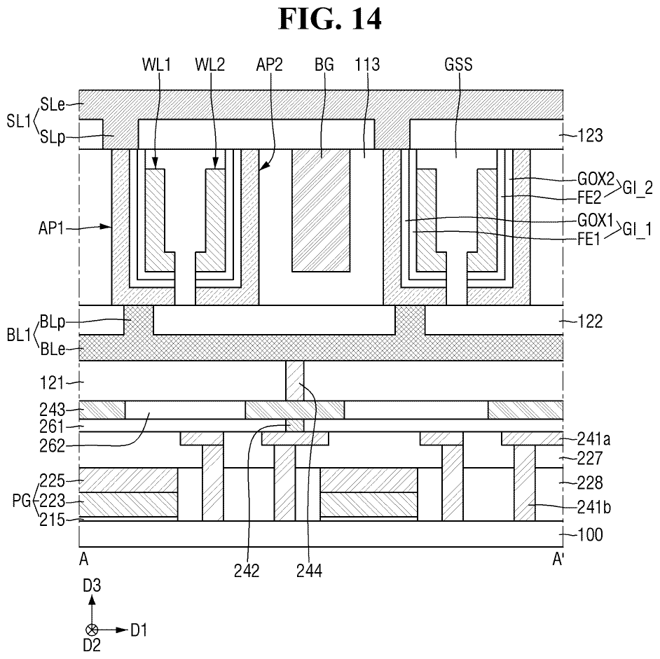

FIG. 14 is a cross-sectional view for describing a semiconductor memory device according to some example embodiments. For convenience of explanation, points different from those described with reference to FIGS. 1 to 7 will be mainly described.

Referring to FIG. 14, a semiconductor memory device according to some example embodiments may further include a peripheral gate structure PG.

The peripheral gate structure PG may be disposed on the substrate 100. The peripheral gate structure PG may be included in a sensing transistor, a transmission transistor, a driving transistor, and the like. Types of transistors disposed in the peripheral gate structure PG may vary depending on a design arrangement of the semiconductor memory device.

The peripheral gate structure PG may include a peripheral gate insulating film 215, a lower peripheral conductive pattern 223, and an upper peripheral conductive pattern 225. The peripheral gate insulating film 215 may include, for example, a silicon oxide film, a silicon oxynitride film, a high-k insulating film having a higher dielectric constant than that of the silicon oxide film, and/or a combination thereof. The high-k insulating film may include, for example, metal oxide, metal oxynitride, metal silicon oxide, and/or metal silicon oxynitride, but is not limited thereto.

Each of the lower peripheral conductive pattern 223 and the upper peripheral conductive pattern 225 may include a conductive material. For example, each of the lower peripheral conductive pattern 223 and the upper peripheral conductive pattern 225 may include a doped semiconductor material, a conductive metal nitride, a conductive metal silicon nitride, a metal carbonitride, a conductive metal silicide, a conductive metal oxide, a two-dimensional material, and/or a metal. It is illustrated that the peripheral gate structure PG includes a plurality of conductive patterns (e.g., the lower peripheral conductive patterns 223 and the upper peripheral conductive patterns 225), but the present disclosure is not limited thereto.

A first peripheral lower insulating film 227 and a second peripheral lower insulating film 228 may be disposed on the substrate 100. Each of the first peripheral lower insulating film 227 and a second peripheral lower insulating film 228 may include an insulating material.

A first peripheral wiring line 241a and a peripheral contact plug 241b may be disposed in the first peripheral lower insulating film 227 and the second peripheral lower insulating film 228. It is illustrated that the first peripheral wiring line 241a and the peripheral contact plug 241b are disposed in different films, but the present disclosure is not limited thereto. A boundary between the first peripheral wiring line 241a and the peripheral contact plug 241b may not be distinguished. Each of the first peripheral wiring line 241a and the peripheral contact plug 241b may include, for example, a conductive material.

A first peripheral upper insulating film 261 and a second peripheral upper insulating film 262 may be disposed on the first peripheral wiring line 241a and the peripheral contact plug 241b. The second peripheral upper insulating film 262 may be on the first peripheral upper insulating film 261. Each of the first peripheral upper insulating film 261 and the second peripheral upper insulating film 262 may include, for example, an insulating material.

A second peripheral wiring line 243 and a peripheral via plug 242 may be disposed on the first peripheral wiring line 241a. The peripheral via plug 242 may be disposed in the first peripheral upper insulating film 261. The second peripheral wiring line 243 may be disposed in the second peripheral upper insulating film 262.

The second peripheral wiring line 243 and the peripheral via plug 242 may be connected to the first peripheral wiring line 241a. The peripheral via plug 242 may connect the first peripheral wiring line 241a and the second peripheral wiring line 243. Each of the second peripheral wiring line 243 and the peripheral via plug 242 may include, for example, a conductive material. It is illustrated that the second peripheral wiring line 243 and the peripheral via plug 242 are different films, but the present disclosure is not limited thereto. For example, the peripheral via plug 242 and the second peripheral wiring line 243 may form a unitary structure. A boundary between the second peripheral wiring line 243 and the peripheral via plug 242 may not be distinguished.

The first source line SL1, the second source line SL2, the first bit line BL1, the second bit line BL2, the first word line WL1, the second word line WL2, the back gate electrode BG, the first channel pattern AP1, and the second channel pattern AP2 may be disposed on the peripheral gate structure PG.

A cell connection plug 244 may be disposed in the first lower insulating film 121. The cell connection plug 244 may be connected to the second peripheral wiring line 243. The cell connection plug 244 may include, for example, a conductive material.

The first bit line BL1 may be disposed on the cell connection plug 244. The first bit line BL1 may be connected to the cell connection plug 244. Although not illustrated, the second bit line (BL2 in FIG. 1) may be disposed on the cell connection plug 244 and be connected to the cell connection plug 244.

The descriptions of the first source line SL1, the second source line SL2, the first bit line BL1, the second bit line BL2, the first word line WL1, the second word line WL2, the back gate electrode BG, the first channel pattern AP1, and the second channel pattern AP2 may be substantially the same as those described with reference to FIGS. 1 to 13, and therefore may be omitted below.

The protrusion GSS_P (referring to GSS_P in FIG. 6) of the gate separation pattern GSS may protrude from the horizontal portion GSS_H (referring to GSS_H in FIG. 6) of the gate separation pattern GSS toward the bit lines BL1 and BL2 in the third direction D3. The protrusion GSS_P of the gate separation pattern GSS may protrude from the horizontal portion GSS_H of the gate separation pattern GSS toward the peripheral gate structure PG in the third direction D3. The protrusion GSS_P of the gate separation pattern GSS may be closer to the peripheral gate structure PG than the horizontal portion GSS_H of the gate separation pattern GSS.

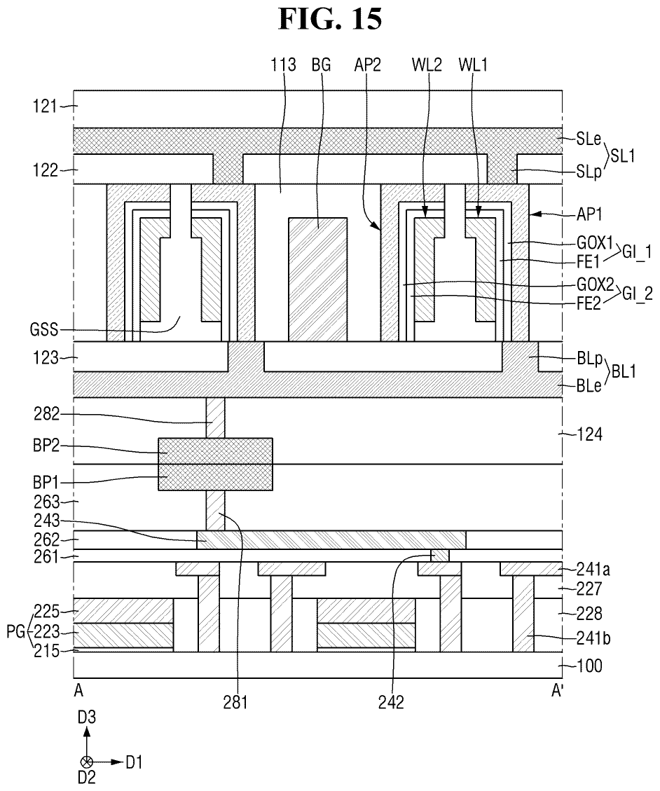

FIG. 15 is a cross-sectional view for describing a semiconductor memory device according to some example embodiments. For convenience of explanation, portions different from those described with reference to FIG. 14 will be mainly described.

Referring to FIG. 15, a semiconductor memory device according to some example embodiments may further include a first bonding pad BP1 and a second bonding pad BP2.

The first bonding pad BP1 and a first pad plug 281 may be disposed on the second peripheral wiring line 243. A third peripheral upper insulating film 263 may be disposed on the second peripheral upper insulating film 262. The first bonding pad BP1 and the first pad plug 281 may be disposed in the third peripheral upper insulating film 263.

The first pad plug 281 may be disposed between the first bonding pad BP1 and the second peripheral wiring line 243. The first pad plug 281 may connect the first bonding pad BP1 and the second peripheral wiring line 243.

The second bonding pad BP2 and a second pad plug 282 may be disposed on the first bonding pad BP1. A fourth lower insulating film 124 may be disposed on the third peripheral upper insulating film 263. The second bonding pad BP2 and the second pad plug 282 may be disposed in the fourth lower insulating film 124.

The second bonding pad BP2 may be connected (e.g., electrically connected) to the first bonding pad BP1. For example, the second bonding pad BP2 may be in contact with the first bonding pad BP1. Since the second bonding pad BP2 is electrically connected to the first bonding pad BP1, the second bonding pad BP2 may be connected (e.g., electrically connected) to the first and second peripheral wiring lines 241a and 243.

The first bit line BL1 may be disposed on the second bonding pad BP2. Although not illustrated, the second bit line (BL2 in FIG. 1) may be disposed on the second bonding pad BP2.

The second pad plug 282 may be disposed between the first bit line BL1 and the second bonding pad BP2. The second pad plug 282 may connect (e.g., electrically connect) the first bit line BL1 and the second bonding pad BP2.

Since the second bonding pad BP2 is connected (e.g., electrically connected) to the first bonding pad BP1, the first and second peripheral wiring lines 241a and 243 may be connected (e.g., electrically connected) to the first bit line BL1 and the second bit line BL2.

The first pad plug 281 and the second pad plug 282 may include, for example, a conductive material including metal. Each of the first bonding pad BP1 and the second bonding pad BP2 may include a conductive material including metal. It is illustrated that each of the first bonding pad BP1 and the second bonding pad BP2 is a single film, but this is only for convenience of explanation and the present disclosure is not limited thereto.

Each of the fourth lower insulating film 124 and the third peripheral upper insulating film 263 may include, for example, an insulating material. It is illustrated that a boundary between the fourth lower insulating film 124 and the third peripheral upper insulating film 263 is distinguished, but this is only for convenience of explanation and the present disclosure is not limited thereto. For example, the fourth lower insulating film 124 and the third peripheral upper insulating film 263 may form a unitary structure. When the fourth lower insulating film 124 and the third peripheral upper insulating film 263 include the same material, the boundary between the fourth lower insulating film 124 and the third peripheral upper insulating film 263 may not be distinguished. In this case, the boundary between the fourth lower insulating film 124 and the third peripheral upper insulating film 263 may be distinguished using a boundary between the first bonding pad BP1 and the second bonding pad BP2.

Although not illustrated, a bonding insulating film may be further disposed between the fourth lower insulating film 124 and the third peripheral upper insulating film 263. For example, the bonding insulating film may include SiCN, but is not limited thereto.

The first source line SL1, the second source line SL2, the first word line WL1, the second word line WL2, the back gate electrode BG, the first channel pattern AP1, and the second channel pattern AP2 may be disposed on the first bit line BL1 and the second bit line BL2.

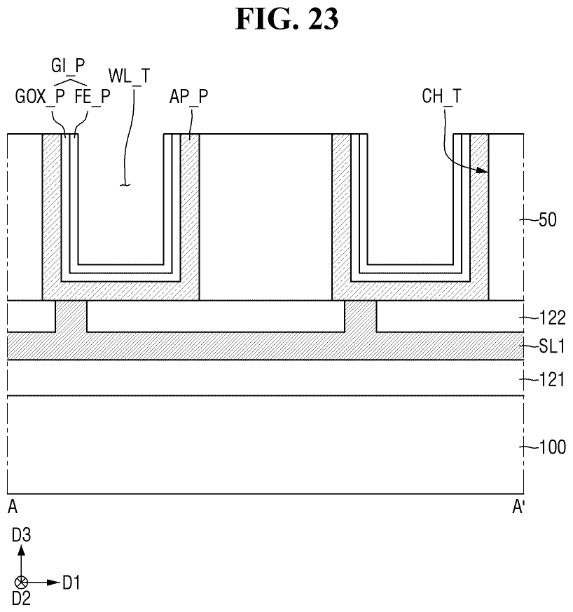

FIGS. 16 to 32 are views for describing a method for manufacturing a semiconductor memory device according to some example embodiments.

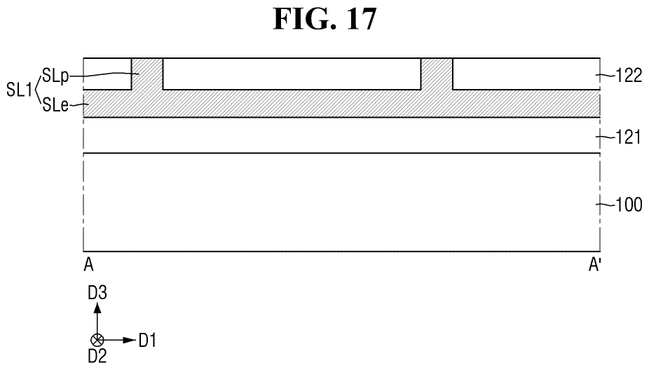

Referring to FIGS. 16 and 17, the first lower insulating film 121 may be formed on the substrate 100.

The first source line SL1 and the second source line SL2 may be formed on the first lower insulating film 121. Each of the first and second source lines SL1 and SL2 may include a source line extension SLe and source line protrusions SLp. The second lower insulating film 122 may be formed on the first lower insulating film 121. The second lower insulating film 122 may be formed around the first source line SL1 and the second source line SL2. The second lower insulating film 122 may not cover or may not overlap an upper surface of the source line protrusion SLp of the first source line SL1 and an upper surface of the source line protrusion SLp of the second source line SL2.

For example, the source line extension SLe of the first source line SL1 and the source line extension SLe of the second source line SL2 may be formed on the first lower insulating film 121. The source line extensions SLe of the first and second source lines SL1 and SL2 and a portion of the second lower insulating film 122 may be formed on the first lower insulating film 121.

Then, the source line protrusion SLp of the first source line SL1 and the source line protrusion SLp of the second source line SL2 may be formed. A remainder of the second lower insulating film 122 may be formed around the source line protrusions SLp of the first and second source lines SL1 and SL2.

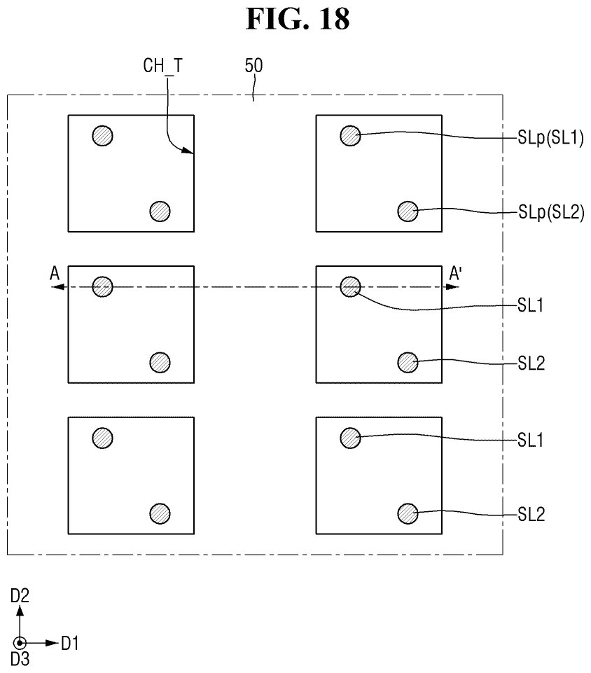

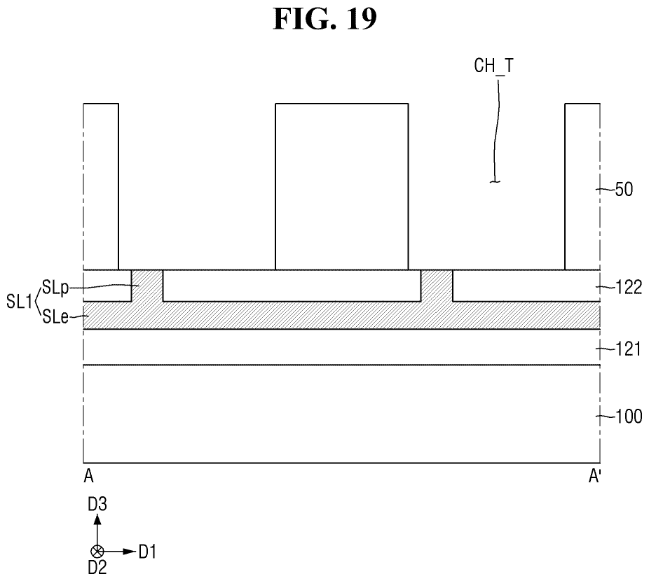

Referring to FIGS. 18 and 19, a sacrificial film 50 may be formed on the second lower insulating film 122.

The sacrificial film 50 may include a plurality of channel trenches CH_T. The plurality of channel trenches CH_T may be arranged in a lattice shape along the first direction D1 and the second direction D2.

In a plan view, each channel trench CH_T may have, for example, a quadrangular shape. Each channel trench CH_T may expose one source line protrusion SLp included in the first source line SL1 and one source line protrusion SLp included in the second source line SL2.

The sacrificial film 50 may include, for example, an insulating material. The sacrificial film 50 may include a material having an etch selectivity with respect to the second lower insulating film 122. For example, when the second lower insulating film 122 includes silicon oxide, the sacrificial film 50 may include silicon nitride, but is not limited thereto.

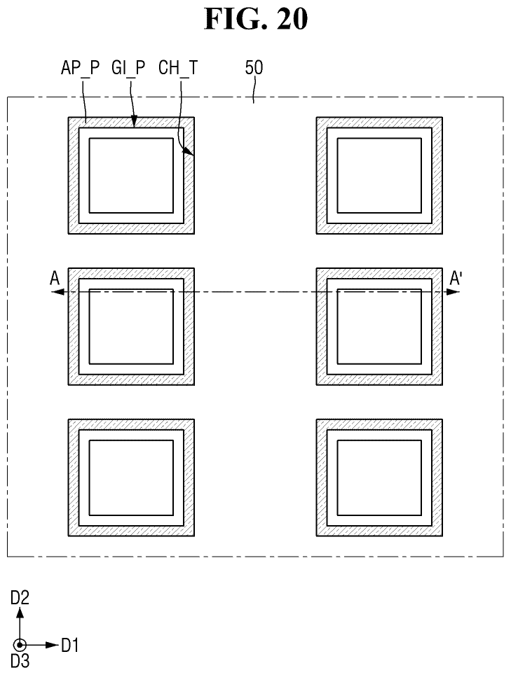

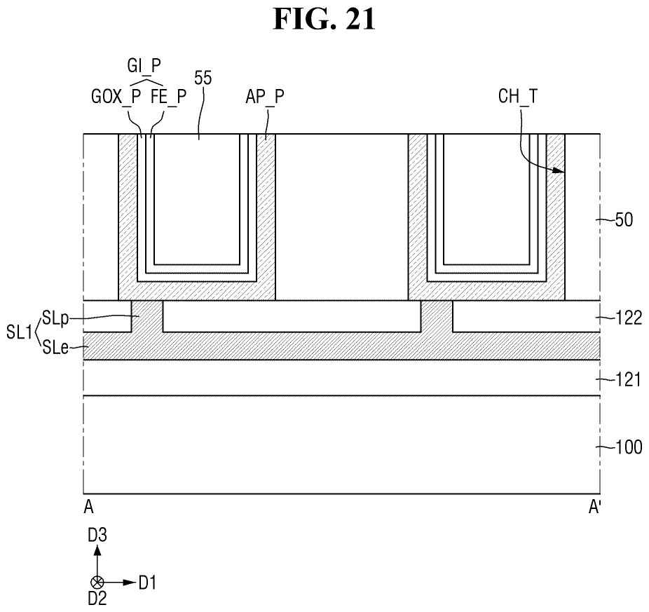

Referring to FIGS. 20 and 21, a pre-channel pattern AP_P may be formed in each channel trench CH_T.

The pre-channel pattern AP_P may be formed along sidewalls and a lower surface of the channel trench CH_T. The pre-channel pattern AP_P may be connected to the exposed source line protrusion SLp of the first source line SL1. The pre-channel pattern AP_P may be connected to the exposed source line protrusion SLp of the second source line SL2.

A pre-gate insulating film GI_P may be formed on the pre-channel pattern AP_P. The pre-gate insulating film GI_P may be formed in each channel trench CH_T. The pre-gate insulating film GI_P may be formed along the sidewalls and lower surface of the channel trench CH_T. The pre-gate insulating film GI_P may be formed along the sidewalls and lower surface of the pre-channel pattern AP_P. The pre-gate insulating film GI_P may include a pre-gate insulating oxide film GOX_P and a pre-ferroelectric material film PE_P.

A sacrificial filling pattern 55 may be formed on the pre-gate insulating film GI_P. The sacrificial filling pattern 55 may fill the channel trench CH_T remaining after the pre-channel pattern AP_P and the pre-gate insulating film GI_P are formed. The sacrificial filling pattern 55 may include the same material as the sacrificial film 50.

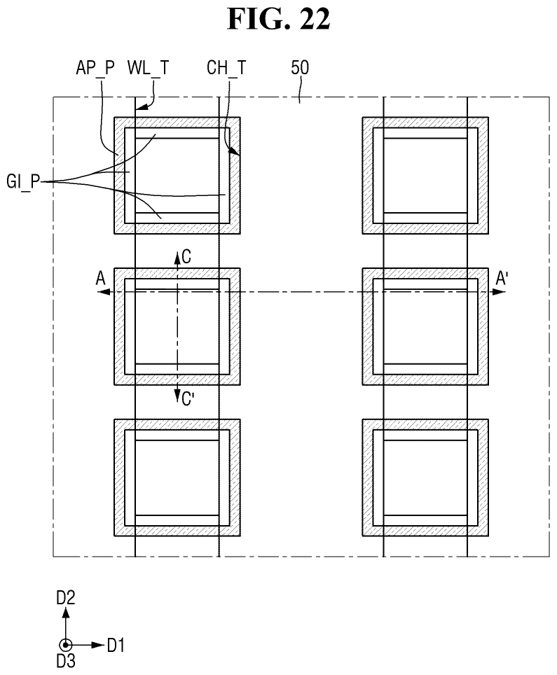

Referring to FIGS. 22 to 24, a word line trench WL_T may be formed on the second lower insulating film 122.

The word line trench WL_T may be formed by removing a portion of the sacrificial film 50 (and/or the sacrificial filling pattern 55), a portion of the pre-channel pattern AP_P, and a portion of the pre-gate insulating film GI_P. While the word line trench WL_T is formed, the sacrificial filling pattern 55 may be removed. The word line trench WL_T may extend to be long in the second direction D2.

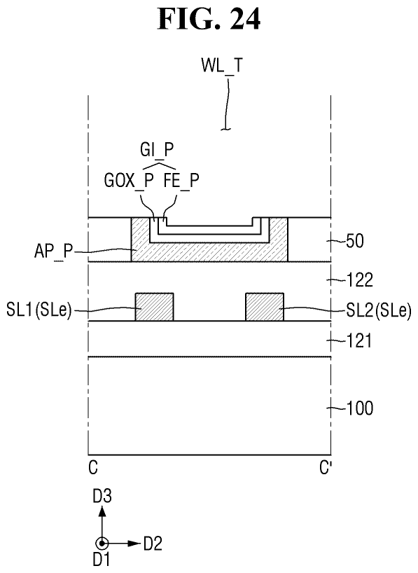

While the word line trench WL_T is formed, the pre-channel pattern AP_P and the pre-gate insulating film GI_P may not be separated into two portions. In FIG. 24, a lower surface of the word line trench WL_T may be defined by the sacrificial film 50, the pre-channel pattern AP_P, and the pre-gate insulating film GI_P.

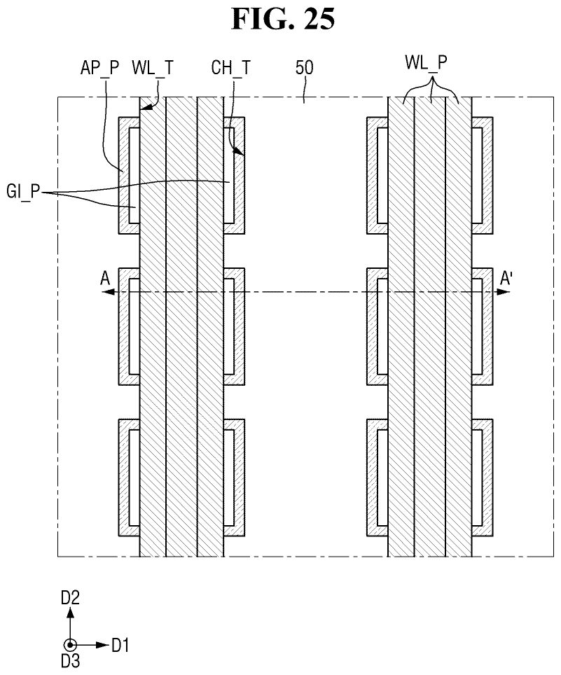

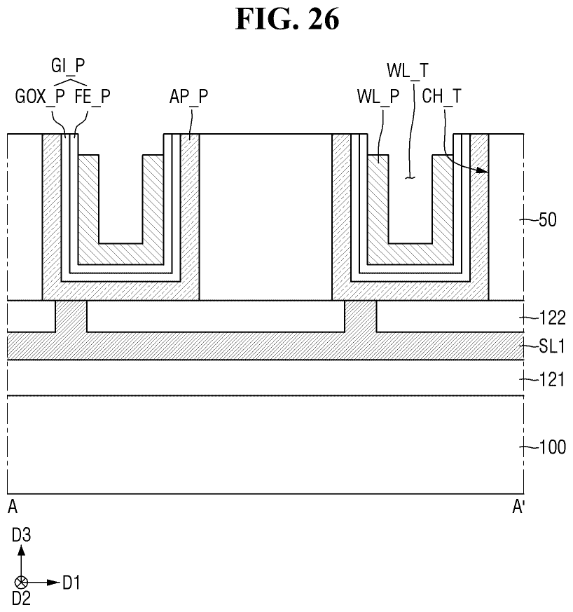

Referring to FIGS. 25 and 26, pre-word lines WL_P may be formed in the word line trench WL_T.

The pre-word line WL_P may be formed along sidewalls and a lower surface of the word line trench WL_T. The pre-word line WL_P may extend to be long in the second direction D2.

The pre-word line WL_P may not extend to an upper surface of the sacrificial film 50. For example, with respect to the upper surface of the substrate 100, the uppermost portion of the pre-word line WL_P may be lower than the upper surface of the sacrificial film 50 in the third direction D3. The uppermost portion of the pre-word line WL_P may be closer than the upper surface of the sacrificial film 10 to the upper surface of the substrate 100.

Unlike illustrated, the pre-word line WL_P may extend to the upper surface of the sacrificial film 50.

Unlike described above, as an example, after the word line trench WL_T is formed, the pre-gate insulating film GI_P may be formed. The pre-gate insulating film GI_P may extend in the second direction D2 along the word line trench WL_T. In some embodiments, before the word line trench WL_T is formed, the pre-gate insulating oxide film GOX_P of the pre-gate insulating film GI_P may be formed. In addition, after the word line trench WL_T is formed, the pre-ferroelectric material film PE_P may be formed.

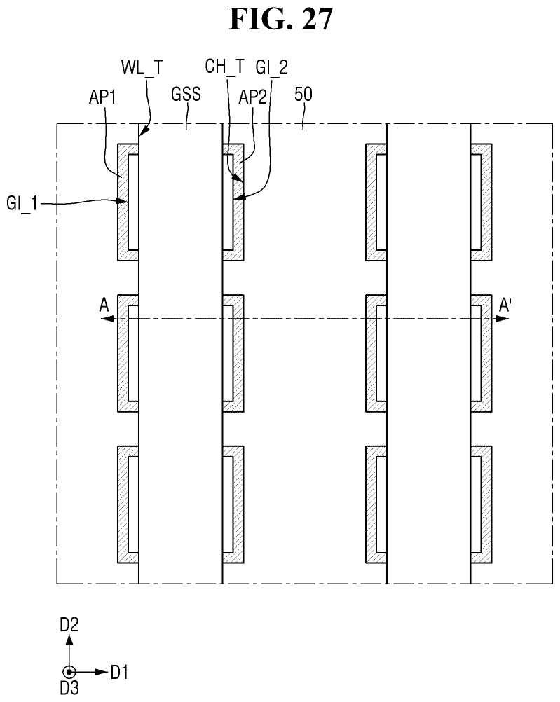

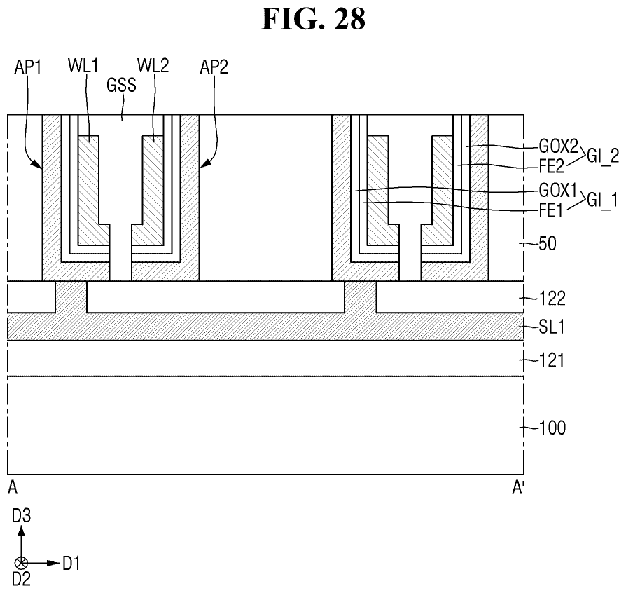

Referring to FIGS. 27 and 28, the first word line WL1 and the second word line WL2 may be formed in the word line trench WL_T by separating the pre-word line WL_P.

The first channel pattern AP1 and the second channel pattern AP2 may be formed by separating the pre-channel pattern AP_P. The first gate insulating film GI_1 and the second gate insulating film GI_2 may be formed by separating the pre-gate insulating film GI_P.

The gate separation pattern GSS may be formed on the first word line WL1 and the second word line WL2. The gate separation pattern GSS may extend along the second direction D2. An upper surface of the gate separation pattern GSS may be coplanar with the upper surface of the sacrificial film 50.

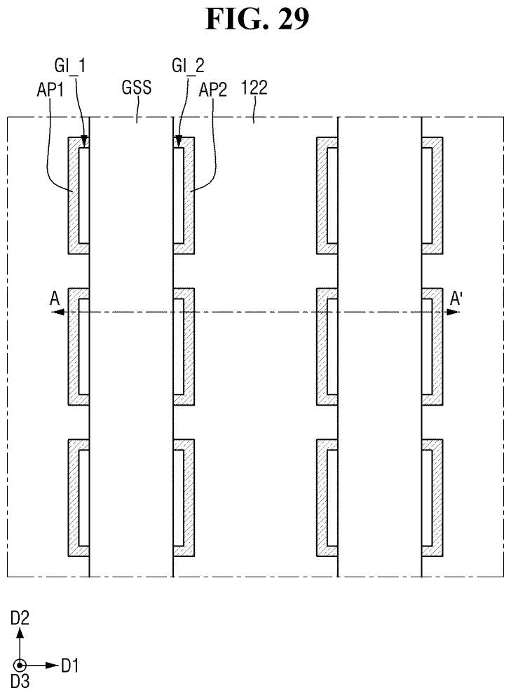

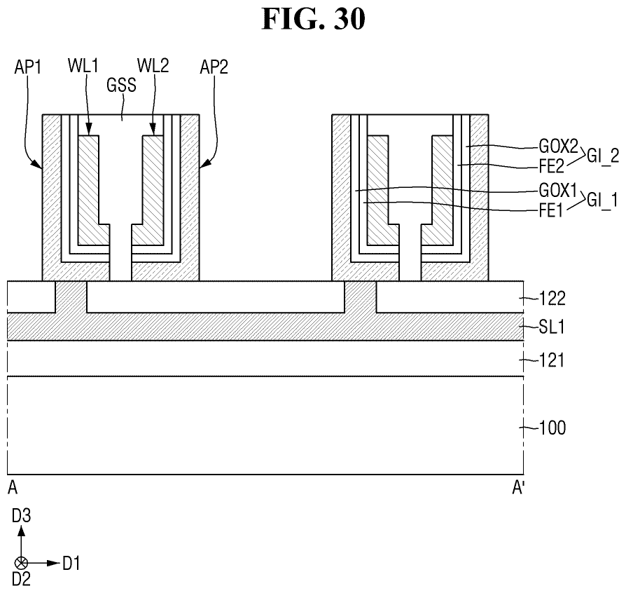

Referring to FIGS. 29 and 30, the second lower insulating film 122 may be exposed by removing the sacrificial film 50.

A back gate trench extending in the second direction D2 may be formed between the gate separation patterns GSS adjacent to each other in the first direction D1. Sidewalls of the back gate trench may be defined by the first channel pattern AP1, the second channel pattern AP2, and the gate separation pattern GSS.

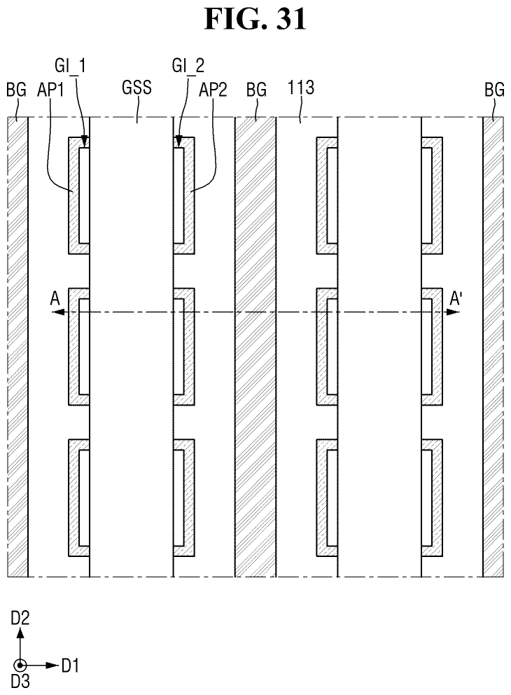

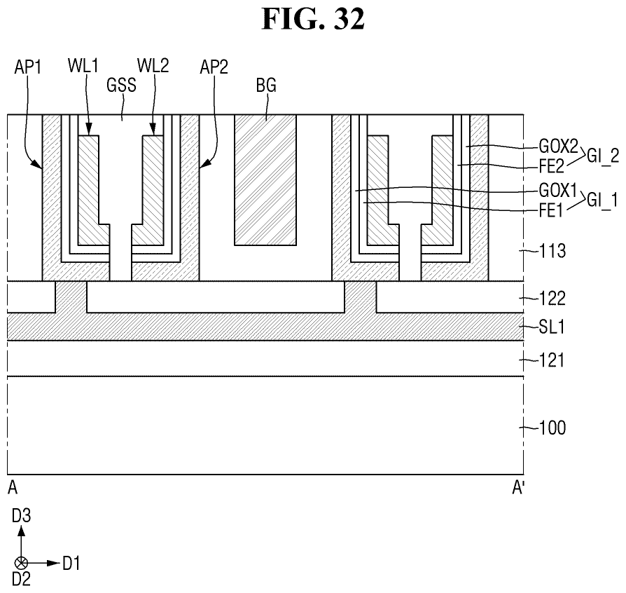

Referring to FIGS. 31 and 32, a back gate electrode BG may be formed between the gate separation patterns GSS adjacent to each other in the first direction D1.

For example, the back gate insulating film 113 may be formed along sidewalls and a lower surface of the back gate trench. A back gate recess may be defined by the back gate insulating film 113. Subsequently, the back gate electrode BG may fill the back gate recess.

Subsequently, referring to FIGS. 3 and 4, the first bit line BL1 and the second bit line BL2 may be formed on the back gate electrode BG, the first word line WL1, the second word line WL2, the first channel pattern AP1, and the second channel pattern AP2.

In concluding the detailed description, those skilled in the art will appreciate that many variations and modifications may be made to the embodiments without substantially departing from the scope of the present inventive concept. Therefore, the disclosed preferred embodiments of the invention are used in a generic and descriptive sense only and not for purposes of limitation.

What is claimed is:

1. A semiconductor memory device comprising:
a first word line extending in a first direction;
a second word line spaced apart from the first word line in a second direction that intersects the first direction, wherein the second word line extends in the first direction;
a back gate electrode between the first word line and the second word line, wherein the back gate electrode extends in the first direction;
a first channel pattern between the first word line and the back gate electrode;
a second channel pattern between the second word line and the back gate electrode;
a first gate insulating film between the first word line and the first channel pattern, wherein the first gate insulating film includes a first ferroelectric material film;
a second gate insulating film between the second word line and the second channel pattern, wherein the second gate insulating film includes a second ferroelectric material film;
a first bit line on the first channel pattern and the second channel pattern, wherein the first bit line extends in the second direction and is connected to the first channel pattern; and
a second bit line on the first channel pattern and the second channel pattern,
wherein the second bit line is spaced apart from the first bit line in the first direction, and
wherein the second bit line extends in the second direction and is connected to the second channel pattern.

2. The semiconductor memory device of claim 1, further comprising a back gate insulating film between the back gate electrode and the first channel pattern and between the back gate electrode and the second channel pattern.

3. The semiconductor memory device of claim 2, wherein the first gate insulating film includes a gate insulating oxide film between the first ferroelectric material film and the first channel pattern, and
a thickness of the gate insulating oxide film in the second direction is different from a thickness of the back gate insulating film in the second direction.

4. The semiconductor memory device of claim 1, further comprising:
a first source line that is connected to the first channel pattern and spaced apart from the second channel pattern; and
a second source line that is connected to the second channel pattern and spaced apart from the first channel pattern.

5. The semiconductor memory device of claim 1, wherein the first bit line includes a line extension that extends in the second direction and a line protrusion that protrudes from the line extension in a third direction that intersects the first direction and the second direction, and
wherein the first channel pattern is in contact with the line protrusion.

6. The semiconductor memory device of claim 1, wherein the first channel pattern includes a vertical portion that extends in a third direction and a horizontal portion that extends in the second direction.

7. The semiconductor memory device of claim 6, wherein the vertical portion of the first channel pattern includes a first vertical portion and a second vertical portion,
wherein the first vertical portion of the first channel pattern and the second vertical portion of the first channel pattern are directly connected to each other,
wherein the first vertical portion of the first channel pattern includes a first sidewall and a second sidewall opposite to each other in the second direction, and
wherein the first sidewall of the first vertical portion of the first channel pattern faces the back gate electrode.

8. The semiconductor memory device of claim 1, wherein the first word line includes a vertical portion that extends in a third direction and a horizontal portion that extends in the second direction in a cross-sectional view.

9. The semiconductor memory device of claim 1, wherein the first channel pattern and the second channel pattern each include polysilicon and/or metal oxide.

10. A semiconductor memory device comprising:
a first source line that extends in a first direction;
a second source line that extends in the first direction, wherein the second source line is spaced apart from the first source line in a second direction that intersects the first direction;
a first word line on the first source line and the second source line, wherein the first word line extends in the second direction;
a second word line on the first source line and the second source line, wherein the second word line is spaced apart from the first word line in the first direction and extends in the second direction;
a first channel pattern between the first word line and the second word line, wherein the first channel pattern is connected to the first source line;
a second channel pattern between the first word line and the second word line, wherein the second channel pattern is connected to the second source line;
a first gate insulating film between the first word line and the first channel pattern, wherein the first gate insulating film includes a first ferroelectric material film;
a second gate insulating film between the second word line and the second channel pattern, wherein the second gate insulating film includes a second ferroelectric material film;
a first bit line on the first channel pattern and the second channel pattern, wherein the first bit line is connected to the first channel pattern and extends in the first direction; and
a second bit line on the first channel pattern and the second channel pattern, wherein the second bit line is connected to the second channel pattern and spaced apart from the first bit line in the second direction, and
wherein the second bit line extends in the first direction.

11. The semiconductor memory device of claim 10, wherein the first source line and the first bit line each include a line extension that extends in the first direction and a line protrusion that protrudes from the line extension in a third direction that intersects the first direction and the second direction, and
wherein the first channel pattern is in contact with the line protrusion of the first source line and the line protrusion of the first bit line.

12. The semiconductor memory device of claim 10, further comprising a back gate electrode on the first source line and the second source line, wherein the back gate electrode is between the first word line and the second word line.

13. The semiconductor memory device of claim 12, further comprising a back gate insulating film between the back gate electrode and the first channel pattern,
wherein the first gate insulating film includes a gate insulating oxide film between the first ferroelectric material film and the first channel pattern, and
wherein a thickness of the gate insulating oxide film in the first direction is less than a thickness of the back gate insulating film in the first direction.

14. The semiconductor memory device of claim 10, wherein the first channel pattern includes a vertical portion that extends in a third direction and a horizontal portion that extends in the second direction.

15. The semiconductor memory device of claim 10, wherein the first channel pattern and the second channel pattern each include polysilicon and/or metal oxide.

16. A semiconductor memory device comprising:
a peripheral gate structure on a substrate;
back gate electrodes on the peripheral gate structure, wherein the back gate electrodes extend in a first direction;
a first word line between a first back gate electrode and a second back gate electrode among the back gate electrodes, wherein the first back gate electrode and the second back gate electrode are adjacent to each other in a second direction that intersects the first direction, and wherein the first word line extends in the first direction;
a second word line between the first back gate electrode and the second back gate electrode, wherein the second word line extends in the first direction;
a first channel pattern between the first back gate electrode and the first word line;
a second channel pattern between the second back gate electrode and the second word line;
a gate separation pattern between the first word line and the second word line, wherein the gate separation pattern includes a horizontal portion and a protrusion, wherein the protrusion of the gate separation pattern protrudes from the horizontal portion of the gate separation pattern in a third direction that intersects the first direction and the second direction, wherein a width of the horizontal portion of the gate separation pattern in the second direction is greater than a width of the protrusion of the gate separation pattern in the second direction, and wherein the protrusion of the gate separation pattern is closer than the horizontal portion of the gate separation pattern to the peripheral gate structure in the third direction;
a first gate insulating film between the first word line and the first channel pattern, wherein the first gate insulating film includes a first ferroelectric material film;
a second gate insulating film between the second word line and the second channel pattern, wherein the second gate insulating film includes a second ferroelectric material film;
a first bit line on the first channel pattern and the second channel pattern, wherein the first bit line is connected to the first channel pattern and extends in the second direction; and
a second bit line on the first channel pattern and the second channel pattern, wherein the second bit line is connected to the second channel pattern, spaced apart from the first bit line in the first direction, and extends in the second direction.

17. The semiconductor memory device of claim 16, further comprising a back gate insulating film between the first back gate electrode and the first channel pattern,
wherein the first gate insulating film includes a gate insulating oxide film between the first ferroelectric material film and the first channel pattern, and
wherein a thickness of the gate insulating oxide film in the second direction is less than a thickness of the back gate insulating film in the second direction.

18. The semiconductor memory device of claim 16, further comprising a first source line and a second source line on the peripheral gate structure and each extends in the second direction,
wherein the first source line is connected to the first channel pattern and spaced apart from the second channel pattern, and
wherein the second source line is connected to the second channel pattern and spaced apart from the first channel pattern.

19. The semiconductor memory device of claim 16, wherein the first channel pattern and the second channel pattern are separated by the protrusion of the gate separation pattern.

20. The semiconductor memory device of claim 16, wherein the first channel pattern and the second channel pattern are connected by a connection channel pattern, and
wherein the gate separation pattern is on the connection channel pattern.
